(19) United States
(12) Patent Application Publication
(10) Pub. No.: US 2025/0040424 A1
(43) Pub. Date: Jan. 30, 2025

(54) DIVALENT PLATINUM COMPLEX AND ORGANIC LIGHT-EMITTING DIODE

(71) Applicant: GUANGDONG AGLAIA OPTOELECTRONIC MATERIALS CO., LTD, Foshan (CN)

(72) Inventors: Xinwei Wu, Foshan (CN); Huiyang Li, Foshan (CN); Lei Dai, Foshan (CN); Lifei Cai, Foshan (CN)

(21) Appl. No.: 18/708,309

(22) PCT Filed: Oct. 4, 2022
(86) PCT No.: PCT/CN2022/123703

§ 371 Date: May 8, 2024

(30) Foreign Application Priority Data
Nov. 10, 2021 (CN) 202111324669.2

(51) Int. Cl. H10K 85/30; C07F 15/00; C09K 11/06; H10K 50/00

(52) U.S. Cl. CPC H10K 85/346; C07F 15/0086; C09K 11/06; C09K 2211/1007; C09K 2211/1029; C09K 2211/185; H10K 50/00

(57) ABSTRACT

The present application relates to a divalent platinum complex with a high color purity, which has a structure of chemical formula (I). The present application further provides an organic electroluminescent device, including a cathode, an anode, and an organic layer. The organic layer includes one or more of a hole injection layer, a hole transport layer, a light-emitting layer, a hole blocking layer, an electron transport layer, or an electron injection layer. At least one layer of the organic layer includes the compound of the structural formula (I).

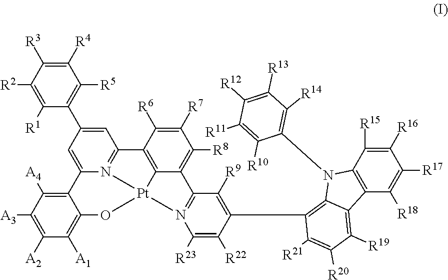

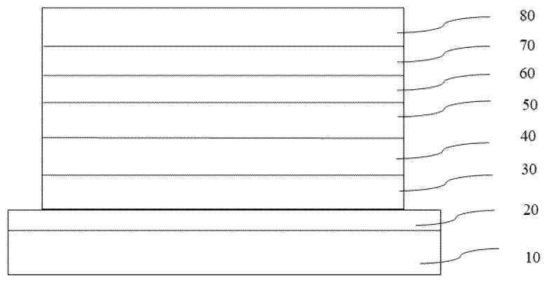

### CROSS-REFERENCE TO RELATED APPLICATIONS

This application is an U.S. national phase application under 35 U.S.C. § 371 based upon international patent application No. PCT/CN2022/123703 filed on Oct. 4, 2022, which itself claims priority to Chinese patent application No. 2021113246692, filed on Nov. 10, 2021. The contents of the above-identified applications are hereby incorporated herein in their entireties by reference.

### TECHNICAL FIELD

The present application relates to the field of luminescent materials, in particular to a divalent platinum complex having a high color purity and a use thereof in an organic light-emitting diode.

### BACKGROUND

With the increasing demand on informatization, new intelligent terminal products are constantly emerging. Especially, electronic products are developing gradually towards intelligent, flexible, and portable designs. The organic light-emitting diode (OLED), as a new type of display technology, have become an important focal point in the development of current material science and industrialization due to its numerous advantages such as ultralight weight and ultrathin thickness, low power consumption, self-luminous, broad operation temperature range, wide color gamut, wide viewing angle, fast response speed, and ease of realization of flexible display.

In the early fluorescent OLED, typically only the singlet state is utilized to emit lights, and the triplet excitons produced in the device cannot be effectively utilized and return to the ground state by non-radiative means, limiting the widespread use of the OLED. The phenomenon of electrophosphorescence was first reported by Zhiming Zhi, et al. at the University of Hong Kong in 1998. In the same year, a phosphorescent OLED was prepared by Thompson et al. with a transition metal complex as a luminescent material. The phosphorescent OLED can efficiently utilize singlet and triplet excitons to emit lights, with a theoretical internal quantum efficiency of 100%, greatly promoting the commercialization of the OLED. The covalent nature of metal-carbon bonds in the electrophosphorescent metal complex enhances the mixing of metal d orbitals and ligand orbitals, thereby increasing the stability of the compound. Additionally, due to the strong heavy-atom effect, the mixing of metal d orbitals and ligand orbitals can amplify the influence of the metal center on the excited states of the ligands and enhance the spin-orbit coupling effect, thereby increasing the quantum yield of triplet states and promoting efficient phosphorescent radiation relaxation. After nearly two decades of research and development on the electrophosphorescent OLED, this OLED material has entered the application stage. In the application stage, to meet the demand for high-quality full-color emission in devices, materials with high quantum efficiency and good color purity performance are necessary. This necessitates the development of new efficient narrow-bandgap complex materials for OLED.

### SUMMARY

In view of the above-mentioned problems in the prior art, the present application provides a divalent platinum complex having a high color purity, which exhibits a good photoelectric property when applied to an organic light-emitting diode.

The present application further provides an organic light-emitting diode based on the divalent platinum complex having the high color purity.

The divalent platinum complex having the high color purity is a compound having a structure of formula (I):

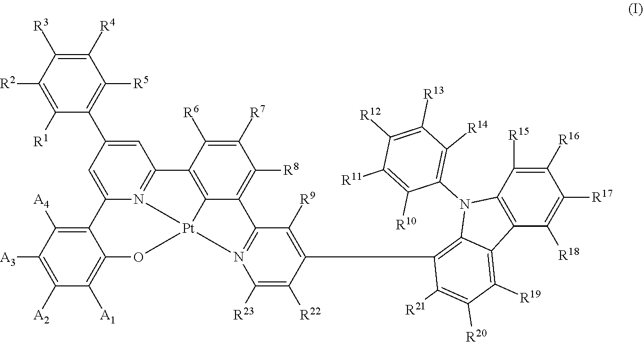

wherein:
R¹ to R²³ are each independently selected from hydrogen, deuterium, halogen, amino, carbonyl, carboxyl, thioalkyl, cyano, sulfonyl, phosphino, a substituted or unsubstituted alkyl having 1 to 20 carbon atoms, a substituted or unsubstituted cycloalkyl having 3 to 20 ring carbon atoms, a substituted or unsubstituted alkenyl having 2 to 20 carbon atoms, a substituted or unsubstituted alkoxy having 1 to 20 carbon atoms, a substituted or unsubstituted aryl having 6 to 30 carbon atoms, or a substituted or unsubstituted heteroaryl having 3 to 30 carbon atoms, or any two adjacent substituents are linked or fused to form a ring;
A₁ to A₄ are each independently selected from hydrogen, deuterium, halogen, amino, carbonyl, carboxyl, thioalkyl, cyano, sulfonyl, phosphino, a substituted or unsubstituted alkyl having 1 to 20 carbon atoms, a substituted or unsubstituted cycloalkyl having 3 to 20 ring carbon atoms, a substituted or unsubstituted alkenyl having 2 to 20 carbon atoms, a substituted or unsubstituted alkoxy having 1 to 20 carbon atoms, an aryl having 6 to 30 carbon atoms, or a substituted or unsubstituted heteroaryl having 3 to 30 carbon atoms, or any two adjacent substituents are connected or fused to form a ring;
a heteroatom in the heteroaryl includes one or more of N, S, or O; and
the “substituted” refers to substitution with halogen, deuterium, amino, cyano, or C1-C4 alkyl.

In an embodiment, R¹ to R²³ are each independently selected from hydrogen, deuterium, halogen, amino, thioalkyl, cyano, a substituted or unsubstituted alkyl having 1 to 6 carbon atoms, a substituted or unsubstituted cycloalkyl having 3 to 6 ring carbon atoms, a substituted or unsubstituted alkenyl having 2 to 6 carbon atoms, a substituted or unsubstituted alkoxy having 1 to 6 carbon atoms, a substituted or unsubstituted aryl having 6 to 12 carbon atoms, or a substituted or unsubstituted heteroaryl having 3 to 6 carbon atoms.

A₁ to A₄ are each independently selected from hydrogen, deuterium, halogen, cyano, a substituted or unsubstituted alkyl having 1 to 20 carbon atoms, a substituted or unsubstituted cycloalkyl having 3 to 20 ring carbon atoms, a substituted or unsubstituted alkenyl having 2 to 20 carbon atoms, an aryl having 6 to 30 carbon atoms, or a substituted or unsubstituted heteroaryl having 3 to 30 carbon atoms.

In an embodiment, R¹ to R²³ are each independently selected from hydrogen, deuterium, halogen, or a substituted or unsubstituted alkyl having 1 to 6 carbon atoms.

One or more of A1 to A4 are each independently selected from halogen, cyano, a substituted or unsubstituted alkyl having 1 to 20 carbon atoms, a substituted or unsubstituted cycloalkyl having 3 to 12 ring carbon atoms, a substituted or unsubstituted alkenyl having 2 to 12 carbon atoms, an aryl having 6 to 30 carbon atoms, or a substituted or unsubstituted heteroaryl having 3 to 30 carbon atoms, and the rest are hydrogen.

In an embodiment, R¹ to R²³ are each independently selected from hydrogen, deuterium, halogen, or a substituted or unsubstituted alkyl having 1 to 6 carbon atoms.

One of A₁ to A₄ is selected from halogen, cyano, a substituted or unsubstituted alkyl having 1 to 6 carbon atoms, a substituted or unsubstituted cycloalkyl having 3 to 12 ring carbon atoms, a substituted or unsubstituted alkenyl having 2 to 12 carbon atoms, an aryl having 6 to 30 carbon atoms, or a substituted or unsubstituted heteroaryl having 3 to 30 carbon atoms, and the rest are hydrogen.

In an embodiment, in general formula (I), R¹ to R²³ are each independently selected from hydrogen, deuterium, methyl, or tert-butyl.

One of A₁ to A₄ is selected from fluorine, cyano, methyl, tert-butyl, phenyl, cyano phenyl, pr pyridyl, and the rest are hydrogen.

In an embodiment, R⁶ to R²³ in R¹ to R²³ are hydrogen.

In an embodiment, at least one of R¹ to R⁵ is not hydrogen.

In an embodiment, R² and R⁴ in R¹ to R⁵ are not hydrogen, and R¹ and R⁵ in R¹ to R⁵ are hydrogen.

Examples of the platinum metal complexes according to the present application are listed below, however, the platinum metal complex is not limited to the listed structures:

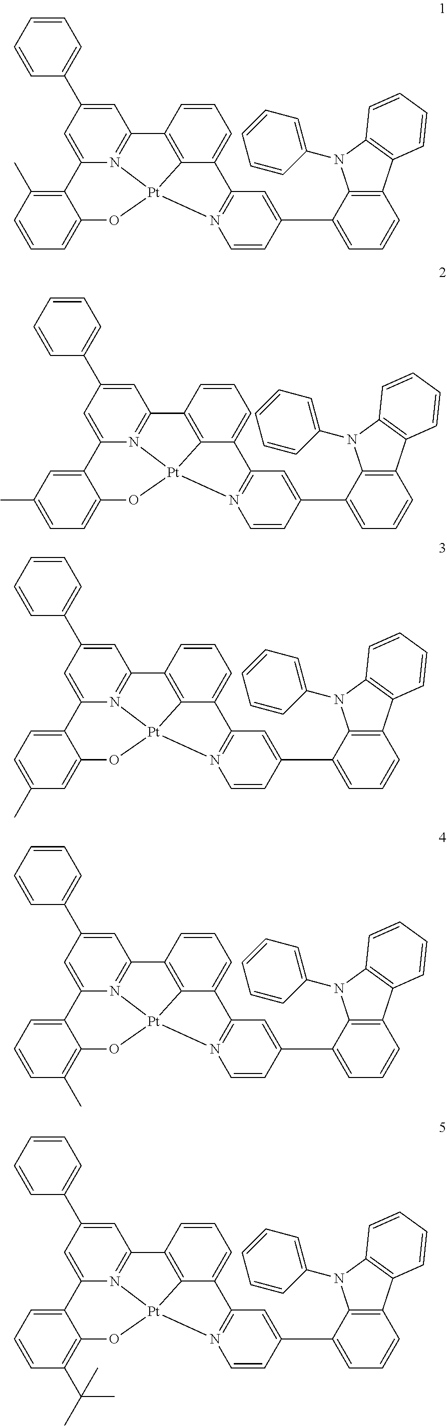

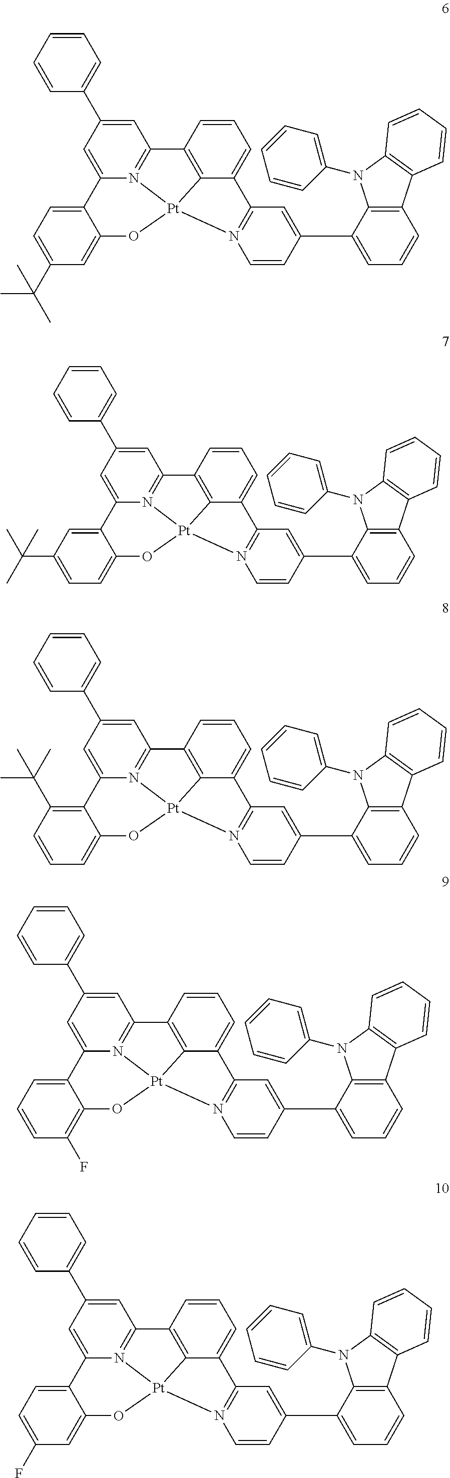

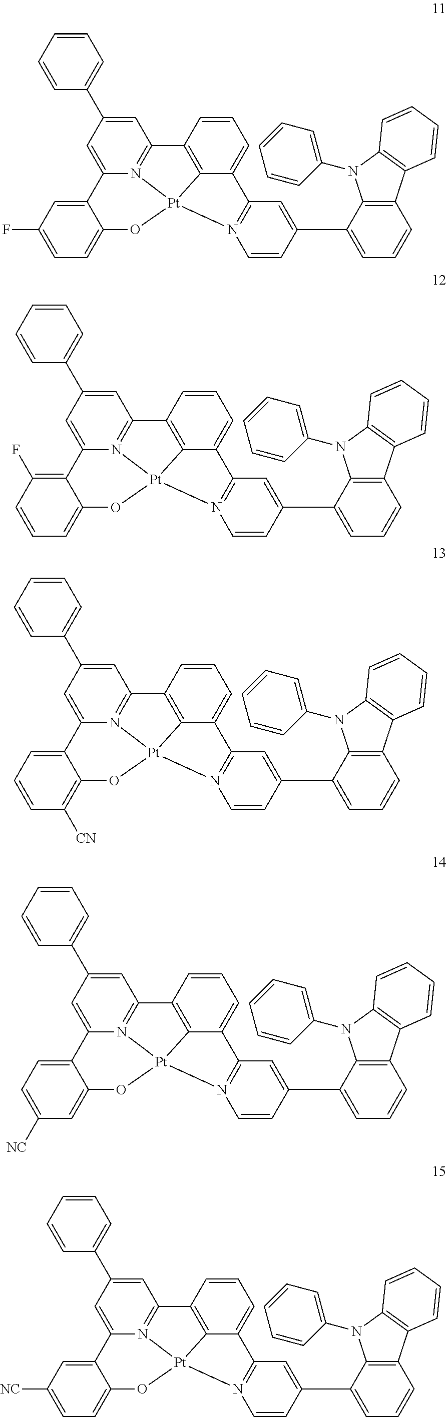

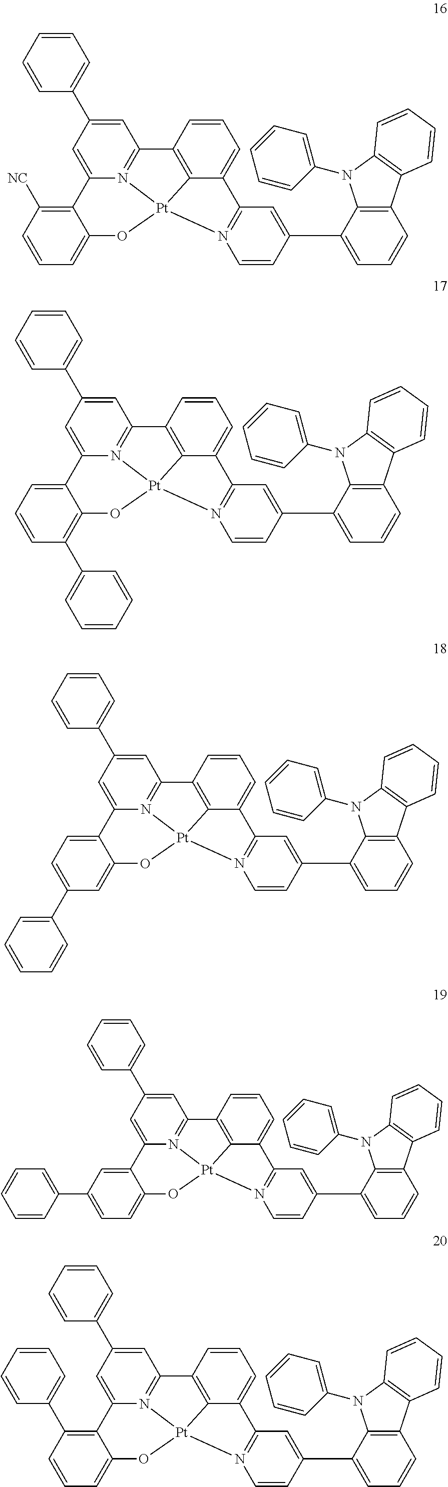

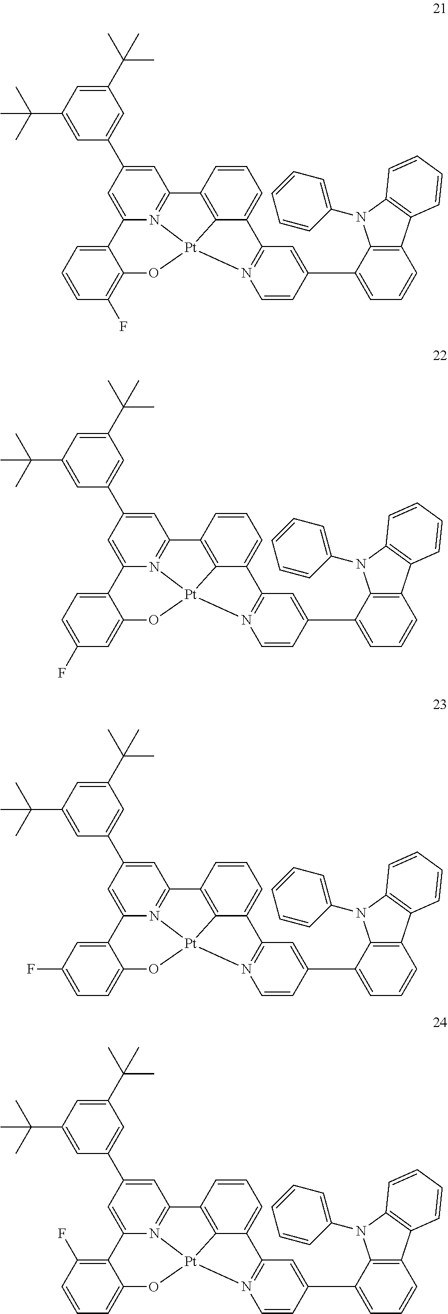

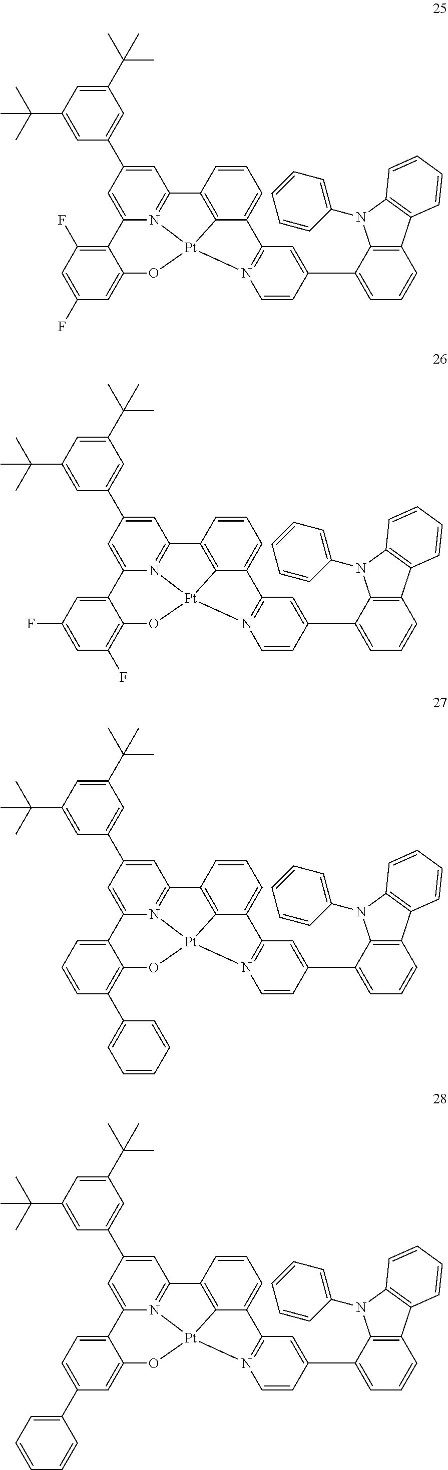

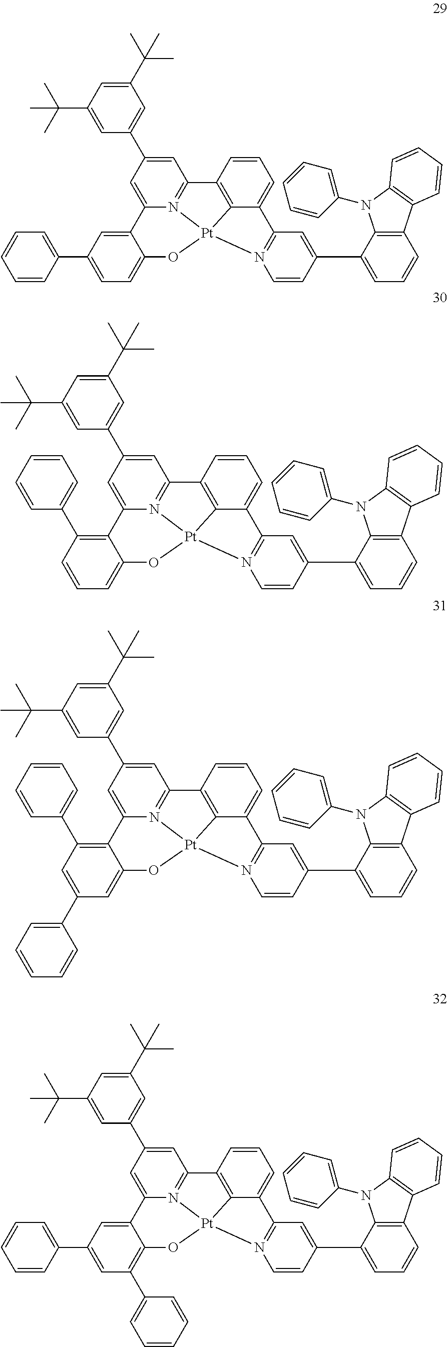

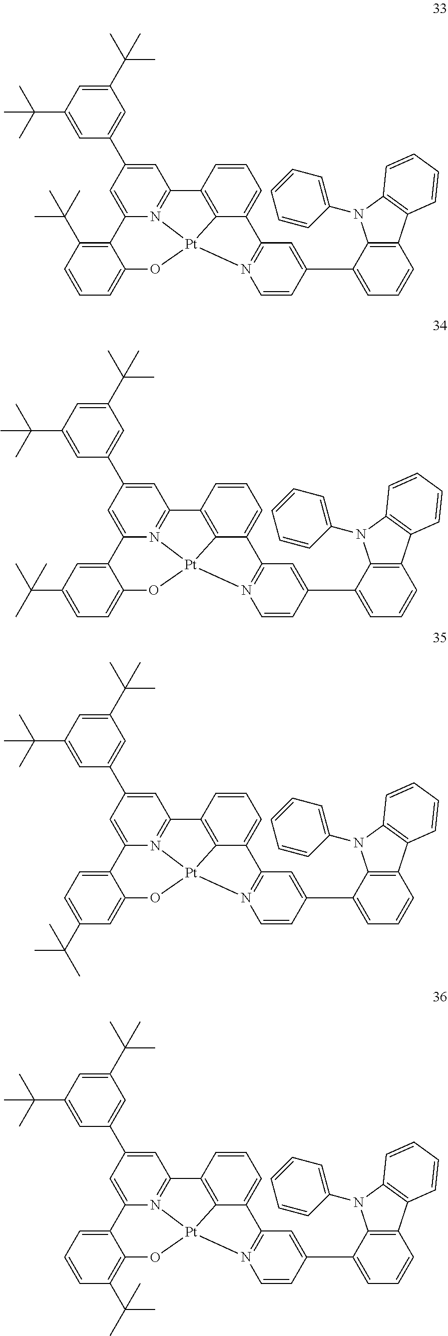

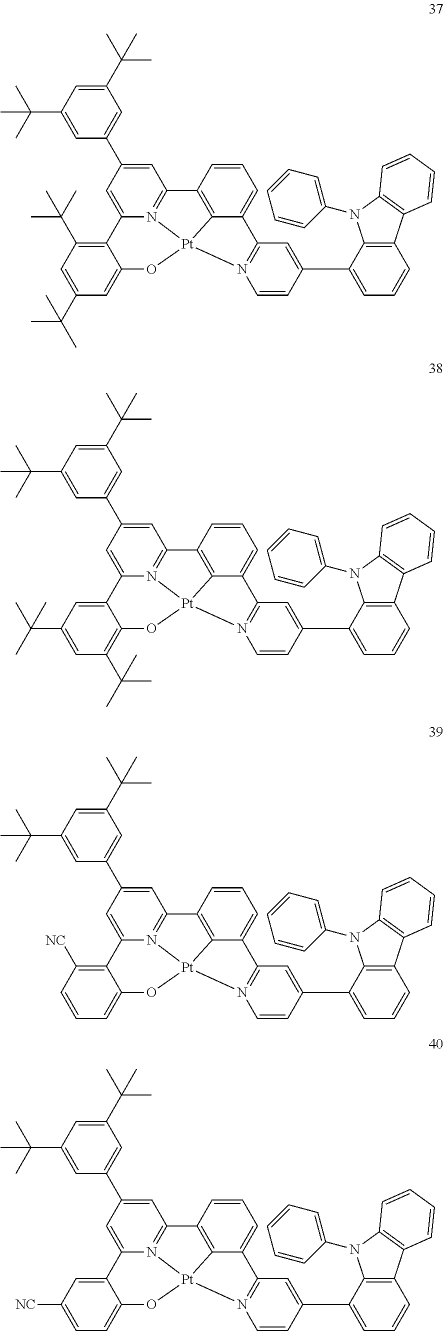

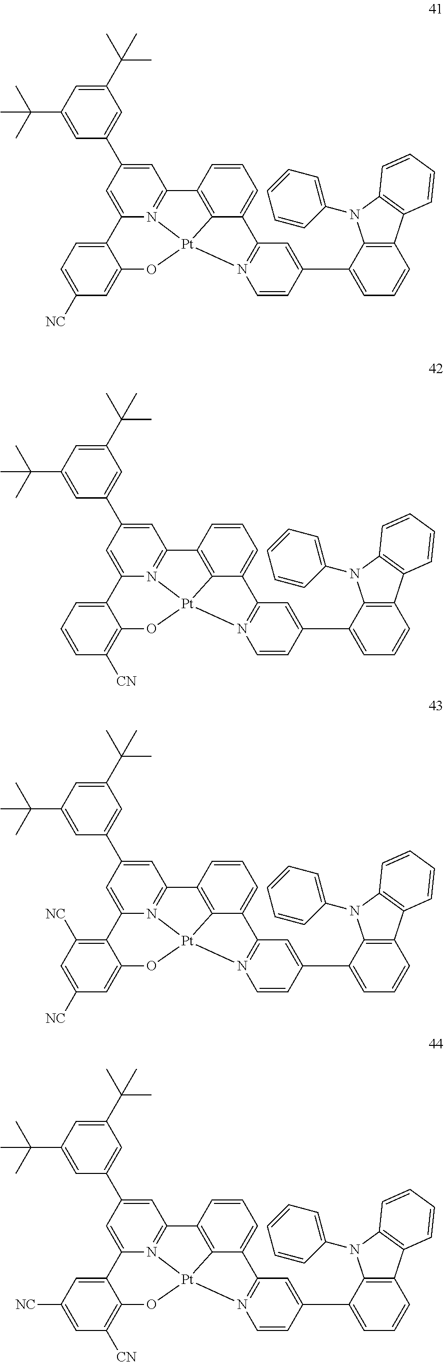

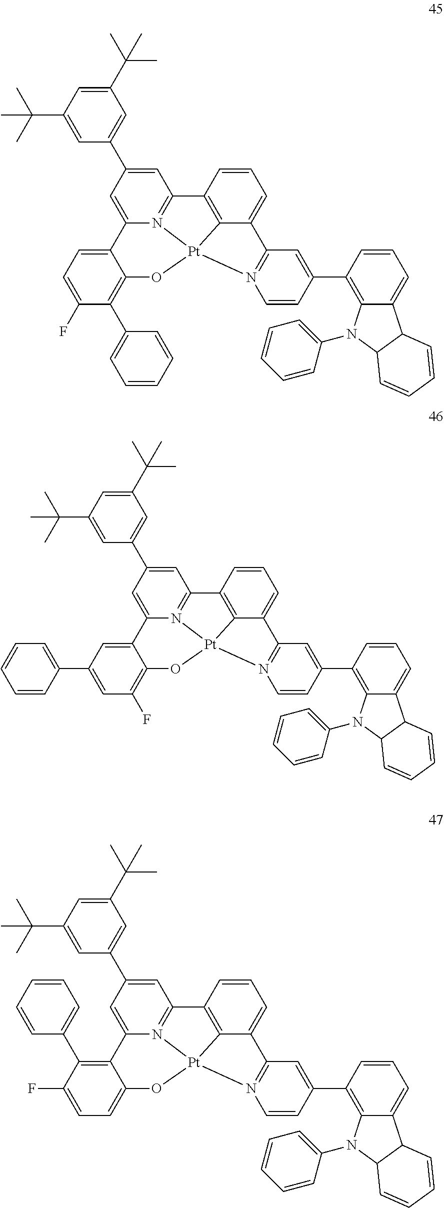

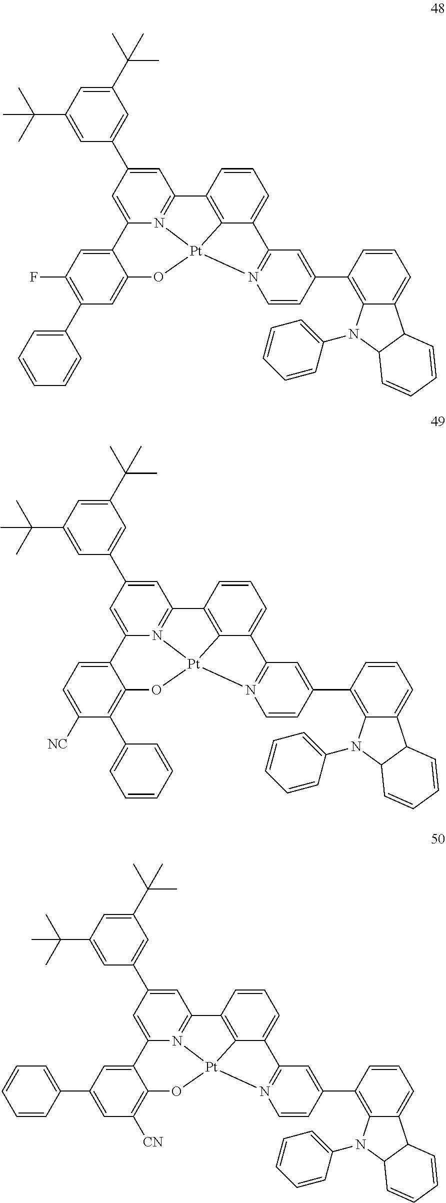

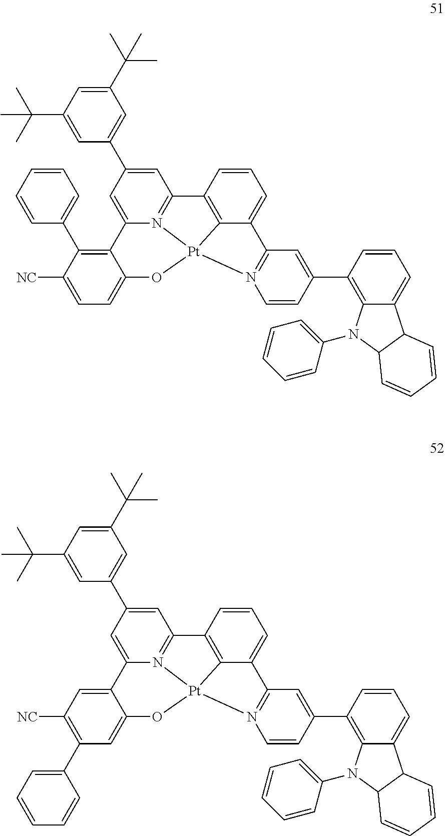

A precursor, i.e., a ligand, of the above-mentioned metal complex has the following structural formula:

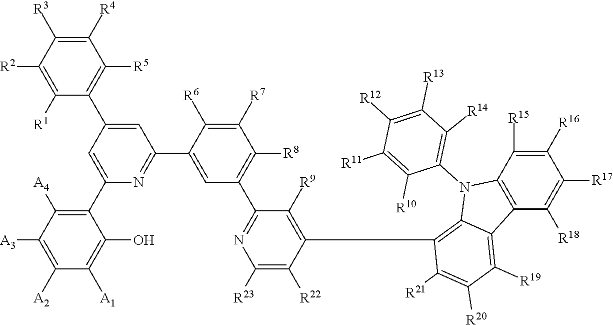

The present application further provides a use of the above-mentioned divalent platinum complex having the high color purity in an organic photoelectronic device. The photoelectronic device includes, but is not limited to, an organic light-emitting diode (OLED), an organic thin film transistor (OTFT), an organic photovoltaic device (OPV), a luminescent electrochemical cell (LCE), and a chemical sensor, for example, OLED.

An organic light-emitting diode (OLED) including the above-mentioned divalent platinum complex having the high color purity is provided, wherein the platinum complex is used as a luminescent material in the light-emitting device.

The organic light-emitting diode in the present application includes a cathode, an anode, and an organic layer. The organic layer includes one or more of a hole injection layer, a hole transport layer, a light-emitting layer, a hole blocking layer, an electron injection layer, or an electron transport layer, and it is not necessary for each of these organic layers to be present. At least one of the hole injection layer, the hole transport layer, the hole blocking layer, the electron injection layer, the light-emitting layer, or the electron transport layer includes the platinum complex of formula (I).

In an embodiment, the layer including the divalent platinum complex having the high color purity of formula (I) is the light-emitting layer or the electron transport layer.

The organic layer in the device of the present application has a total thickness of 1 nm to 1000 nm, such as 1 nm to 500 nm, for example 5 nm to 300 nm.

The organic layer can be a thin film formed by an evaporation method or a solution method.

The present application discloses a series of divalent platinum complexes having the high color purity with novel structures as luminescent materials, which exhibit unexpected characteristics, significantly improved luminous efficiency and device color purity, and good thermal stability, meeting the requirements of an OLED panel for a luminescent material.

The compound causes a low driving voltage, a high luminous efficiency, and a significantly increased color purity when applied to an organic light-emitting diode, having a great potential for the materials to be industrially applied to the field of organic electroluminescent devices.

### BRIEF DESCRIPTION OF THE DRAWING

The FIGURE shows a structural diagram of an organic light-emitting diode device of the present application.

In the FIGURE, 10 denotes a glass substrate, 20 denotes an anode, 30 denotes a hole injection layer, 40 denotes a hole transport layer, 50 denotes a light-emitting layer, 60 denotes an electron transport layer, 70 denotes an electron injection layer, and 80 denotes a cathode.

### DETAILED DESCRIPTION OF THE EMBODIMENTS

There is no requirement on the methods for synthesizing the materials in the present application. In order to describe the present application in more detail, the following examples are provided, but the present application is not limited thereto. The raw materials used in the following synthesis processes are all commercially available products unless otherwise specified.

### Example 1: Synthesis of Complex 22

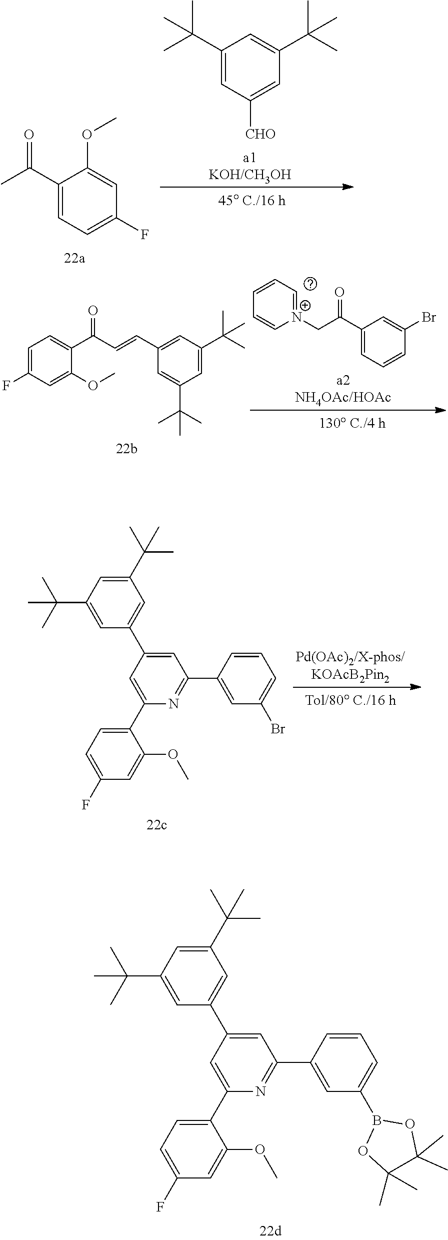 [SMILES: COc1cc(F)ccc1C(C)=O ; CC(C)(C)c1cc(C=O)cc(C(C)(C)C)c1 ; COc1cc(F)ccc1C(=O)/C=C/c1cc(C(C)(C)C)cc(C(C)(C)C)c1 ; O=C(C[n+]1ccccc1)c1cccc(Br)c1 ; COc1cc(F)ccc1-c1cc(-c2cc(C(C)(C)C)cc(C(C)(C)C)c2)cc(-c2cccc(Br)c2)n1 ; COc1cc(F)ccc1-c1cc(-c2cc(C(C)(C)C)cc(C(C)(C)C)c2)cc(-c2cccc(B3OC(C)(C)C(C)(C)O3)c2)n1]

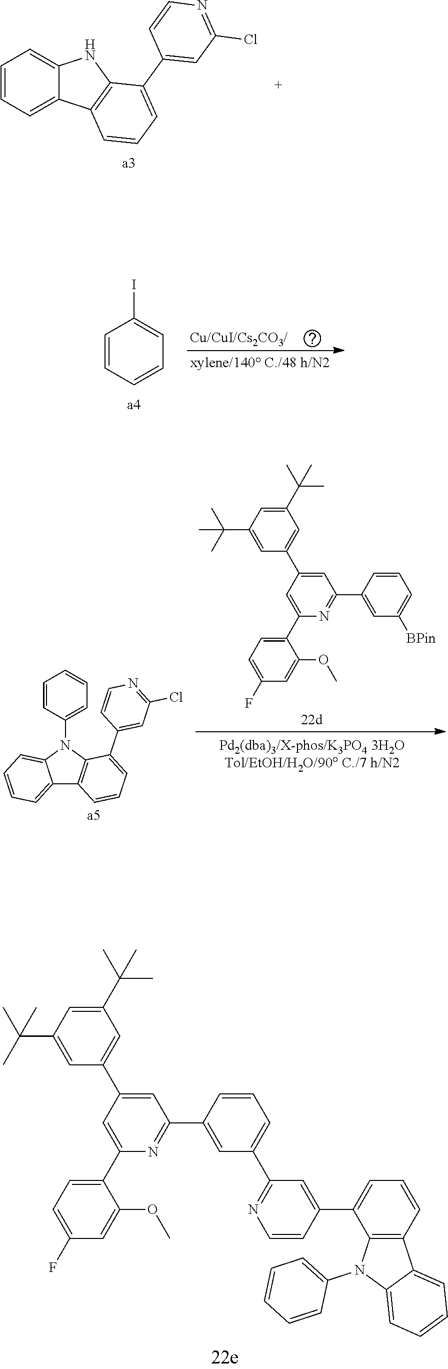

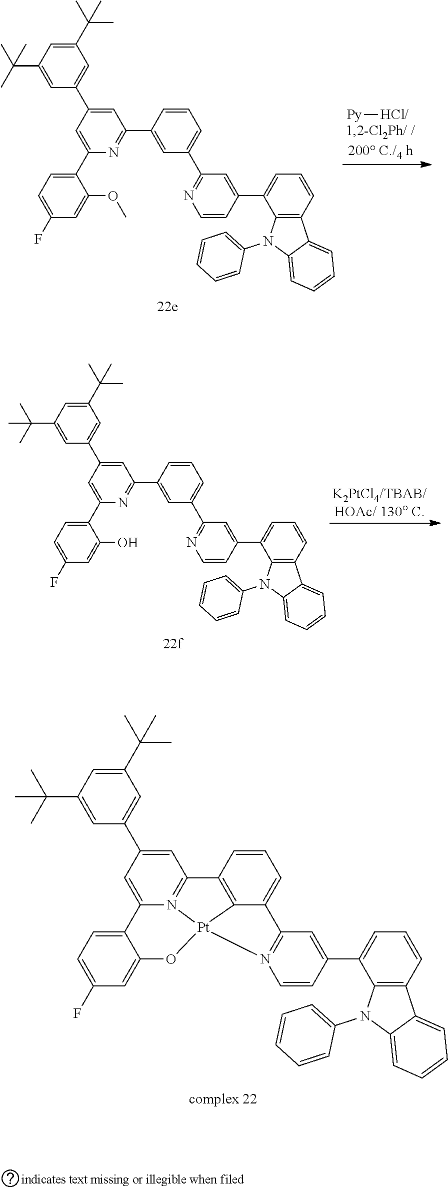

### Synthesis of Compound 22b

22a (10 g, 59.47 mmol, 1.0 eq) was dissolved in methanol (200 ml) in a 1000 ml of single-necked flask. KOH (16.68 g, 297.33 mmol, 5.0 eq) was dissolved in water (100 ml) and the resulting aqueous solution was slowly dropwise added to the flask to obtain a reaction liquid which was then added with a1 (14.28 g, 65.41 mmol, 1.1 eq) and subjected to a reaction at 45° C. for 16 hours under stirring. After the reaction was finished, the reaction liquid was filtered. The filter cake was pulped with methanol (50 ml×2) and then oven-dried to obtain 14 g of white solid with a yield of 63.9%. ¹H NMR (400 MHz, CDCl₃) δ 7.68-7.60 (m, 2H), 7.48 (s, 1H), 7.43 (d, J=1.6 Hz, 2H), 7.34 (d, J=15.9 Hz, 1H), 6.77-6.69 (m, 2H), 3.89 (s, 3H), 1.34 (s, 18H).

### Synthesis of Compound 22c

22b (14 g, 38 mmol, 1.0 eq), a2 (18.42 g, 46 mmol, 1.2 eq), NH₄OAc (87.86 g, 1.14 mol, 30.0 eq), and acetic acid (180 ml) were added to a 500 ml of single-necked flask and subjected to a reaction at 130° C. for 4 hours under the protection of nitrogen. After the reaction was finished, the reaction liquid was filtered to obtain a filter cake, added with water (200 ml), and then extracted with DCM (100 ml×2). The organic phase was subjected to a rotary evaporation to obtain a residue. The residue and the filter cake were pulped with hexane (Hex):ethyl acetate (EA)=20:1 (V/V, a total of 200 ml) and filtered to obtain a filter cake which was oven-dried to obtain 17 g of gray white solid with a yield of 81.38%.

¹H NMR (400 MHz, CDCl₃) δ 8.30 (s, 1H), 8.03 (dd, J=10.3, 4.9 Hz, 3H), 7.78 (d, J=1.3 Hz, 1H), 7.53 (dd, J=14.1, 3.2 Hz, 4H), 7.37 (t, J=7.9 Hz, 1H), 6.85 (td, J=8.4, 2.4 Hz, 1H), 6.77 (dd, J=11.0, 2.3 Hz, 1H), 3.90 (s, 3H), 1.42 (s, 18H).

### Synthesis of Compound 22d

22c (17 g, 31 mmol, 1.0 eq), bis(pinacolato)diboron (15.8 g, 62 mmol, 2.0 eq), Pd(OAc)₂ (69.84 mg, 0.311 mmol, 0.01 eq), KOAc (9.16 g, 93 mmol, 3.0 eq), X-phos (1.48 g, 3.1 mmol, 0.1 eq), and toluene (250 ml) were added to a 1000 ml of single-necked flask and subjected to a reaction at 80° C. for 16 hours under the protection of nitrogen. After the reaction was finished, the reaction liquid was filtered and subjected to a rotary evaporation. The resulting residue was sonicated with hexane (200 mL) for 1 hour, left to stand overnight to precipitate a product, and filtered. The filter cake was grounded and pulped with hexane (200 mL) at 80° C. for 2 hours, filtered, and oven-dried to obtain 11 g of white solid with a yield of 75.79%.

¹H NMR (400 MHz, CDCl₃) δ 8.46 (s, 1H), 8.26 (d, J=7.7 Hz, 1H), 8.09-8.01 (m, 1H), 7.95 (s, 1H), 7.86 (dd, J=9.4, 4.3 Hz, 2H), 7.56-7.48 (m, 4H), 6.87-6.73 (m, 2H), 3.90 (s, 3H), 1.41 (s, 18H), 1.37 (s, 12H).

### Synthesis of Compound a5

a3 (8 g, 29 mmol, 1.0 eq), a4 (17.57 g, 86 mmol, 3.0 eq), Cu (912 mg, 14 mmol, 0.5 eq), CuI (2.73 g, 14 mmol, 0.5 eq), Cs₂CO₃ (28.05 g, 86 mmol, 3.0 eq), o-phenanthroline (5.17 g, 29 mmol, 1.0 eq), and xylene (150 ml) were added to a 250 ml of single-necked flask and subjected to a reaction at 140° C. for 48 hours under the protection of nitrogen. 172 h (17.57 g, 86 mmol, 3.0 eq) was additionally added as the reaction was not completed. a4 (17.57 g, 86 mmol, 3.0 eq) was additionally added as the reaction was still not completed. After the reaction was finished, the reaction liquid was quickly filtered through a silicone funnel (EA), subjected to a rotary evaporation to remove the solvent, and then subjected to a separation by silica gel column chromatography (with Hex:EA=20:1 as an eluent) to obtain 7 g of white solid with a yield of 68.74%.

¹H NMR (400 MHz, CDCl₃) δ 8.26 (dd, J=7.7, 1.1 Hz, 1H), 8.19 (d, J=7.7 Hz, 1H), 8.00 (d, J=5.0 Hz, 1H), 7.45-7.28 (m, 5H), 7.25 (dd, J=9.9, 3.3 Hz, 3H), 7.12-7.04 (m, 2H), 6.99 (s, 1H), 6.93 (dd, J=5.0, 1.4 Hz, 1H).

### Synthesis of Compound 22e

a5 (5 g, 31 mmol, 1.0 eq), 22d (10.04 g, 62 mmol, 2.0 eq), Pd₂(dba)₃ (258 mg, 0.28 mmol, 0.02 eq), K₃PO₄-3H₂O (9.16 g, 42.27 mmol, 3.0 eq), X-phos (672 mg, 1.41 mmol, 0.1 eq), and toluene/ethanol/water (60 mL/15 mL/15 mL) were added to a 500 ml of single-necked flask and subjected to a reaction at 90° C. for 7 hours under the protection of nitrogen. After the reaction was finished, the reaction liquid was added with water (100 ml), extracted with DCM (200 ml), subjected to a rotary evaporation, and subjected to a separation by silica gel column chromatography (with Hex:EA=20:1 (V/V) as an eluent) to obtain 8.5 g of white solid with a yield of 76.75%.

¹H NMR (400 MHz, CDCl₃) δ 8.55 (s, 1H), 8.39 (d, J=5.0 Hz, 1H), 8.26 (dd, J=6.0, 3.0 Hz, 1H), 8.18 (dd, J=15.0, 7.8 Hz, 2H), 8.07-8.01 (m, 1H), 7.99-7.93 (m, 2H), 7.91 (s, 1H), 7.56 (dd, J=18.5, 5.3 Hz, 4H), 7.46 (s, 1H), 7.41 (dd, J=8.2, 5.2 Hz, 3H), 7.33 (t, J=7.3 Hz, 1H), 7.23 (d, J=8.2 Hz, 1H), 7.14-6.99 (m, 6H), 6.78-6.71 (m, 2H), 3.87 (s, 3H), 1.40 (s, 18H).

### Synthesis of Compound 22f

22e (8 g, 10.18 mmol, 1.0 eq), pyridine hydrochloride (80 g), and o-dichlorobenzene (8 ml) were added to a 500 ml of single-necked flask and subjected to a reaction at 200° C. for 4 hours under the protection of nitrogen. After the reaction was finished, the reaction liquid was added with water and extracted with DCM (100 ml×2). The organic phase was subjected to a rotary evaporation and then a separation by silica gel column chromatography (with Hex:EA=5:1 (V/V) as an eluent) to obtain 7.5 g of yellow solid with a yield of 92%.

¹H NMR (400 MHz, CDCl₃) δ 8.41 (s, 1H), 8.38 (d, J=5.0 Hz, 1H), 8.27 (dd, J=5.7, 3.3 Hz, 1H), 8.21 (d, J=7.4 Hz, 1H), 8.02 (d, J=7.8 Hz, 1H), 7.98-7.92 (m, 2H), 7.92-7.87 (m, 2H), 7.65-7.58 (m, 2H), 7.51 (d, J=1.6 Hz, 2H), 7.47 (s, 1H), 7.41 (dd, J=8.8, 5.5 Hz, 3H), 7.33 (t, J=7.0 Hz, 1H), 7.28 (s, 1H), 7.12 (s, 2H), 7.05 (t, J=4.6 Hz, 4H), 6.70-6.60 (m, 2H), 1.42 (s, 18H).

### Synthesis of Complex 22

22f (6.9 g, 8.94 mmol, 1.0 eq), K₂PtCl₄ (4.44 g, 10.74 mmol, 1.2 eq), TBAB (148 mg, 0.45 mmol, 0.05 eq) and acetic acid (750 mL) were added to a 500 ml of single-necked flask and subjected to a reaction at 130° C. for 16 hours under the protection of argon.

After the reaction was finished, the reaction liquid was combined with excess deionized water to precipitate a solid and subjected to a suction filtration. The solid was dissolved into dichloromethane, and subjected to a rotary evaporation, a separation by silica gel column chromatography with dichloromethane as an eluent, a further separation by silica gel column chromatography with Hex:DCM:EA=2:1:0.2 as an eluent, and then a recrystallization with DCM:Hex=10 ml:70 ml to obtain 7 g of red solid, which was recrystallized again with DCM:MeOH=15 ml:15 ml to obtain 6.62 g of red solid with a yield of 69.1%. ¹H NMR (400 MHz, CDCl₃) δ 8.71 (d, J=5.6 Hz, 1H), 8.33-8.28 (m, 1H), 8.23 (d, J=7.4 Hz, 2H), 8.10-8.03 (m, 1H), 7.77 (s, 1H), 7.60 (dd, J=14.6, 6.3 Hz, 4H), 7.44 (t, J=5.7 Hz, 3H), 7.38-7.27 (m, 4H), 7.12 (ddd, J=27.9, 16.7, 8.4 Hz, 7H), 6.96 (d, J=7.2 Hz, 1H), 6.51 (s, 1H), 1.45 (s, 18H).

¹³C NMR (101 MHz, CDCl₃) δ 152.12, 151.60, 148.11, 144.46, 144.34, 141.23, 140.83, 139.59, 139.19, 138.93, 138.92, 137.16, 137.14, 134.48, 130.05, 128.38, 128.33, 128.06, 127.49, 127.27, 127.21, 126.91, 125.82, 125.15, 124.75, 124.17, 123.93, 123.50, 123.47, 123.44, 122.86, 122.84, 122.63, 122.26, 121.69, 121.59, 120.47, 112.54, 108.38, 108.22, 102.14, 101.98, 34.96, 31.29.

ESI-MS (m/z): 965.3 (M+1)

### Example 2

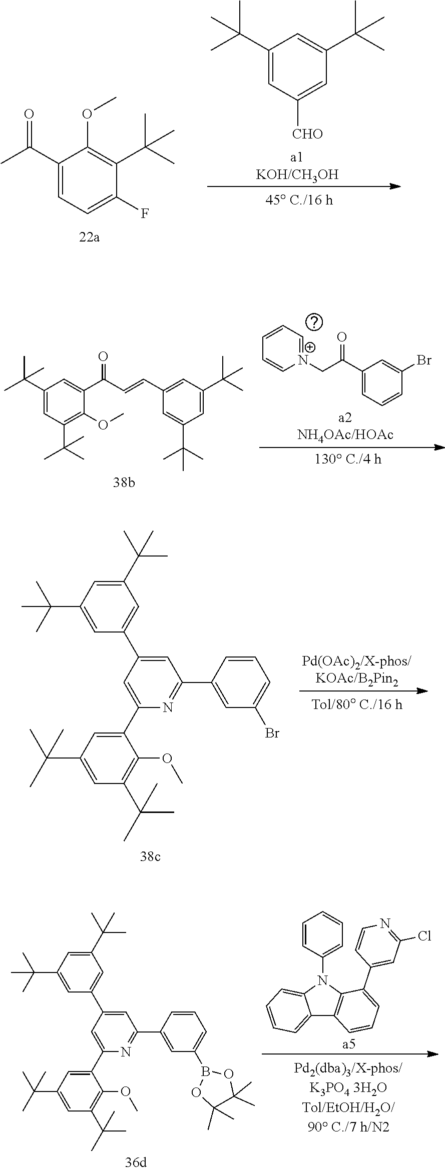

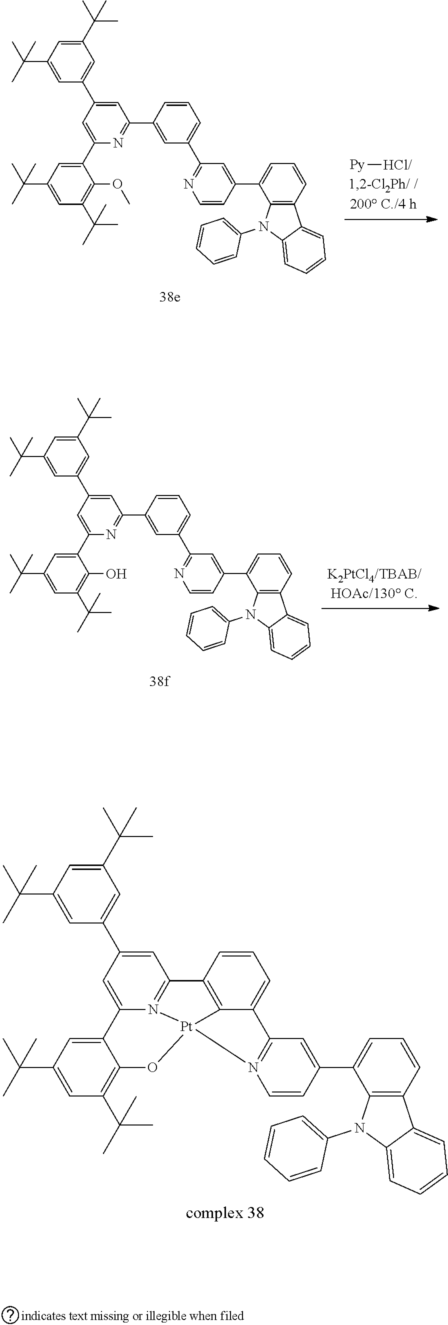

### Synthesis of Compound 38b

38a (8 g, 30.5 mml 1.0 eq) was dissolved in methanol (200 ml) in a 1000 ml of single-necked flask. KOH (8.54 g, 152.5 mmol, 5.0 eq) was dissolved in water (100 ml), and the resulting aqueous solution was slowly dropwise added to the flask to obtain a reaction liquid, which was then added with a1 (7.3 g, 33.55 mmol, 1.1 eq) and subjected to a reaction at 45° C. for 16 hours under stirring. After the reaction was finished, the reaction liquid was filtered. The filter cake was pulped with methanol (50 ml×2) and oven-dried to obtain 7.6 g of white solid with a yield of 53.9%.

¹H NMR (400 MHz, CDCl₃) δ 7.85 (d, J=2.2 Hz, 1H), 7.71 (d, J=15.6 Hz, 1H), 7.60-7.52 (m, 2H), 7.48 (t, J=2.1 Hz, 1H), 7.39 (d, J=2.1 Hz, 2H), 3.87 (s, 3H), 1.42 (s, 9H), 1.36 (s, 18H).

### Synthesis of Compound 38c

38b (7 g, 15.12 mmol. 1.0 eq), a2 (7.3 g, 18.15 mmol, 1.2 eq), NH₄OAc (34.96 g, 453.6 mmol, 30.0 eq), and acetic acid (150 ml) were added to a 500 ml of single-necked flask and subjected to a reaction at 130° C. for 4 hours under the protection of nitrogen. After the reaction was finished, the reaction liquid was filtered to obtain a filter cake, added with water (200 ml), and then extracted with DCM (100 ml×2). The organic phase was subjected to a rotary evaporation to obtain a residue. The residue and the filter cake were pulped with Hex:EA=20:1 (V/V, a total of 200 ml) and filtered to obtain a filter cake which was oven-dried to obtain 7.2 g of gray white solid with a yield of 74.4%.

¹H NMR (400 MHz, CDCl₃) δ 8.22 (t, J=1.9 Hz, 1H), 8.10 (d, J=2.0 Hz, 1H), 8.00 (ddd, J=8.6, 1.9, 1.2 Hz, 1H), 7.93 (d, J=2.0 Hz, 1H), 7.55 (ddd, J=8.1, 2.0, 1.3 Hz, 1H), 7.53-7.49 (m, 2H), 7.46-7.36 (m, 4H), 3.87 (s, 3H), 1.42 (s, 9H), 1.35 (s, 27H).

### Synthesis of Compound 38d

38c (7 g, 10.93 mmol, 1.0 eq), bis(pinacolato)diboron (5.51 g, 21.86 mmol, 2.0 eq), Pd(OAc)₂ (24.47 mg, 0.109 mmol, 0.01 eq), KOAc (3.2 g, 32.79 mmol, 3.0eq), X-phos (0.51 g, 1.09 mmol, 0.1 eq), and toluene (200 ml) were added to a 1000 ml of single-necked flask and subjected to a reaction at 80° C. for 14 hours under the protection of nitrogen. After the reaction was finished, the reaction liquid was filtered and subjected to a rotary evaporation. The obtained residue was sonicated with hexane (200 mL) for 1 hour, left to stand overnight a product was precipitated, and filtered. The filter cake was grounded and pulped with hexane (200 mL) at 80° C. for 2 hours, filtered, and oven-dried to obtain 6.7 g of white solid with a yield of 90.4%.

¹H NMR (400 MHz, CDCl₃) δ 8.08 (d, J=2.2 Hz, 1H), 8.05 (t, J=1.9 Hz, 1H), 7.93 (d, J=2.0 Hz, 1H), 7.78 (ddd, J=7.7, 1.8, 1.1 Hz, 1H), 7.74 (ddd, J=7.1, 1.9, 1.2 Hz, 1H), 7.54-7.49 (m, 3H), 7.43 (dd, J=9.0, 2.2 Hz, 3H), 3.87 (s, 3H), 1.42 (s, 9H), 1.35 (s, 27H), 1.24 (s, 12H).

### Synthesis of Compound 38e

a5 (1.8 g, 5.1 mmol, 1.0 eq), 38d (7 g, 10.2 mmol, 2.0 eq), Pd₂(dba)₃ (57.5 mg, 0.10 mmol, 0.02eq), K₃PO₄-3H₂O (4.07 g, 15.3 mmol, 3.0 eq), X-phos (243 mg, 0.51 mmol, 0.1 eq), and toluene/ethanol/water (60 mL/15 mL/15 mL) were added to a 500 ml of single-necked flask and subjected to a reaction at 90° C. for 7 hours under the protection of nitrogen. After the reaction was finished, the reaction liquid was added with water (100 mL), extract with DCM (200 ml), subjected to a rotary evaporation, and subjected to a separation by silica gel column chromatography (with Hex:EA=5:1 (V/V) as an eluent) to obtain 3.6 g of white solid with a yield of 80.3%.

¹H NMR (400 MHz, CDCl₃) δ 8.75 (d, J=4.6 Hz, 1H), 8.27 (d, J=1.9 Hz, 1H), 8.21 (t, J=2.0 Hz, 1H), 8.18-8.12 (m, 1H), 8.12-8.07 (m, 2H), 7.93 (d, J=2.0 Hz, 1H), 7.89 (dd, J=8.4, 1.7 Hz, 2H), 7.70-7.64 (m, 1H), 7.65-7.60 (m, 2H), 7.57-7.47 (m, 5H), 7.45-7.36 (m, 7H), 7.34-7.28 (m, 2H), 3.87 (s, 3H), 1.42 (s, 9H), 1.35 (s, 27H).

### Synthesis of Compound 38f

38e (3.5 g, 3.97 mmol, 1.0 eq), pyridine hydrochloride (35 g), and o-dichlorobenzene (3.5 ml) were added to a 500 ml of single-necked flask and subjected to a reaction at 200° C. for 4 hours under the protection of nitrogen. After the reaction was finished, the reaction liquid was added with water and extracted with DCM (200 ml×2). The organic phase was subjected to a rotary evaporation and a separation by silica gel column chromatography (with Hex:EA=5:1 (V/V) as an eluent) to obtain 3 g of yellow solid with a yield of 87%.

¹H NMR (400 MHz, CDCl₃) δ 8.75 (d, J=4.6 Hz, 1H), 8.27 (d, J=1.9 Hz, 1H), 8.21 (t, J=2.0 Hz, 1H), 8.18-8.13 (m, 1H), 8.12-8.08 (m, 2H), 7.90 (dd, J=5.4, 2.1 Hz, 2H), 7.88 (d, J=1.7 Hz, 1H), 7.70-7.61 (m, 3H), 7.54 (t, J=7.0 Hz, 1H), 7.52-7.48 (m, 4H), 7.44-7.36 (m, 7H), 7.34-7.28 (m, 2H), 7.23 (d, J=2.2 Hz, 1H), 1.43 (s, 9H), 1.35 (s, 27H).

### Synthesis of Complex 38

38f (2 g, 2.3 mmol, 1.0 eq), KPtCl₄ (1.04 g, 2.77 mmol, 1.2 eq), TBAB (37 mg, 0.115 mmol, 0.05 eq), and acetic acid (200 mL) were added to a 500 ml of single-necked flask and subjected to a reaction at 130° C. for 16 hours under the protection of argon.

After the reaction was finished, the reaction liquid was combined with excess deionized water to precipitate a solid and subjected to a suction filtration. The solid was dissolved into dichloromethane, and subjected to a rotary evaporation, a separation by silica gel column chromatography with dichloromethane as an eluent, a further separation by silica gel column chromatography with Hex:DCM:EA=2:1:0.2 as an eluent, and then a recrystallization with DCM:Hex=10 ml:70 ml to obtain 7 g of red solid, which was recrystallized again with DCM:MeOH=51 ml:15 ml to obtain 1.8 g of red solid with a yield of 75.0%.

¹H NMR (400 MHz, CDCl₃) δ 9.15 (d, J=9.0 Hz, 1H), 8.27 (d, J=2.2 Hz, 1H), 8.17-8.12 (m, 2H), 8.09 (p, J=3.8 Hz, 1H), 7.77-7.69 (m, 2H), 7.69-7.64 (m, 1H), 7.60-7.57 (m, 1H), 7.57-7.53 (m, 3H), 7.52-7.45 (m, 4H), 7.44-7.28 (m, 8H), 7.22-7.15 (m, 2H), 6.91 (s, 1H), 1.40 (s, 9H), 1.35 (s, 27H).

¹³C NMR (101 MHz, CDCl₃) δ 161.88, 152.13, 151.60, 148.13, 145.08, 144.75, 144.40, 140.67, 139.63, 139.61, 139.59, 139.19, 138.93, 138.92, 137.18, 137.14, 134.50, 130.05, 129.70, 128.38, 128.33, 128.06, 127.49, 126.91, 125.15, 124.99, 124.75, 124.17, 123.93, 123.51, 123.50, 123.47, 123.44, 122.86, 122.84, 122.63, 122.50, 121.69, 121.62, 121.59, 120.47, 112.54, 34.96, 34.92, 31.29, 31.27, 30.41.

ESI-MS (m/z): 1059.4 (M+1)

### Example 3

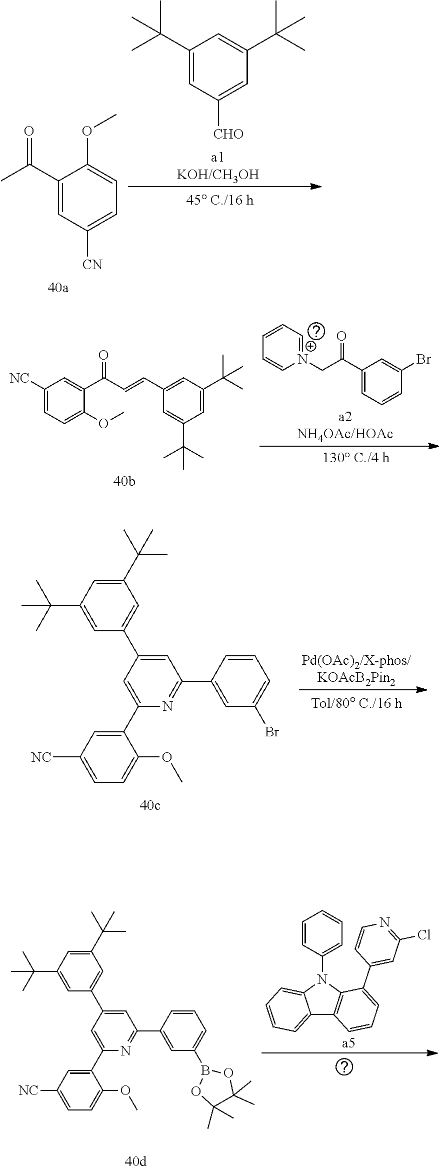

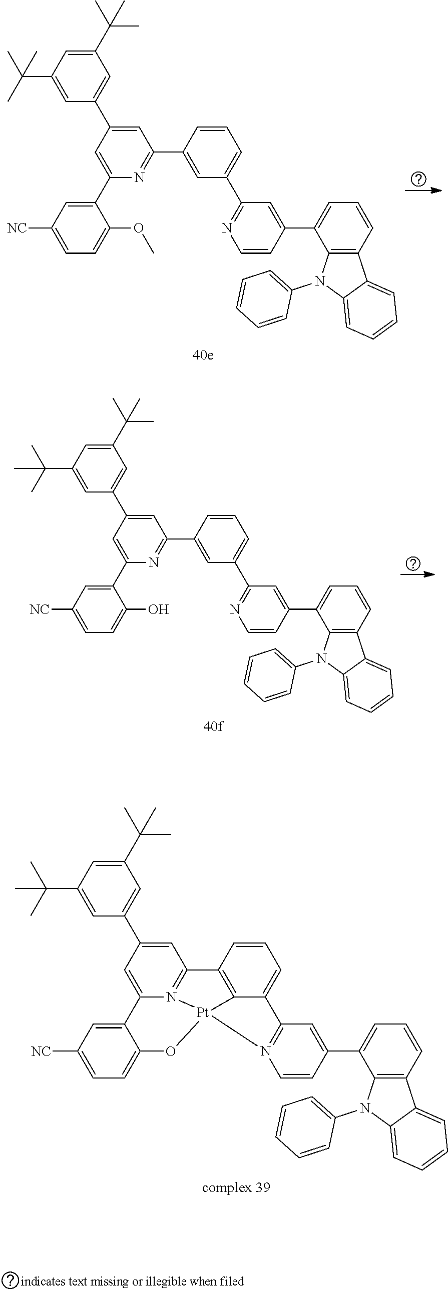

### Synthesis of Compound 40b

40a (10 g, 57.1 mmol, 1.0 eq) was dissolved in methanol (200 ml) in a 1000 ml of single-necked flask. KOH (16.0 g, 285.4 mmol, 5.0 eq) was dissolved in water (100 ml) and the resulting aqueous solution was slowly dropwise added to the flask to obtain a reaction liquid, which was then added with a1 (13.71 g, 62.82 mmol, 1.1 eq) and subjected to a reaction at 45° C. for 16 hours under stirring. After the reaction was finished, the reaction liquid was filtered. The filter cake was pulped with methanol (50 ml×2) and oven-dried to obtain 12.4 g of white solid with a yield of 58.3%. ¹H NMR (400 MHz, CDCl₃) δ 8.14 (d, J=1.9 Hz, 1H), 7.77 (dd, J=8.5, 1.9 Hz, 1H), 7.72 (d, J=15.5 Hz, 1H), 7.57 (d, J=15.4 Hz, 1H), 7.48 (t, J=2.1 Hz, 1H), 7.39 (d, J=2.2 Hz, 2H), 7.22 (d, J=8.4 Hz, 1H), 3.89 (s, 3H), 1.36 (s, 18H).

### Synthesis of Compound 40c

40b (12 g, 32 mmol, 1.0 eq), a2 (15.51 g, 38.4 mmol, 1.2 eq), NH₄OAc (74.0 g, 960 mmol, 30.0 eq), and acetic acid (180 ml) were added to a 500 ml of single-necked flask and subjected to a reaction at 130° C. for 4 hours under the protection of nitrogen. After the reaction was finished, the reaction liquid was filtered to obtain a filter cake, added with water (200 ml), and then extracted with DCM (100 ml×2). The organic phase was subjected to a rotary evaporation to obtain a residue. The residue and the filter cake were pulped with Hex:EA=20:1 (VIV a total of 200 ml) and filtered to obtain a filter cake which was oven-dried to obtain 13.6 g of gray white solid with a yield of 76.8%.

¹H NMR (400 MHz, CDCl₃) δ 8.22 (t, J=2.0 Hz, 1H), 8.13 (d, J=1.9 Hz, 1H), 8.10 (d, J=2.2 Hz, 1H), 8.00 (ddd, J=8.6, 1.9, 1.2 Hz, 1H), 7.96 (d, J=2.2 Hz, 1H), 7.71 (dd, J=8.3, 1.9 Hz, 1H), 7.55 (ddd, J=8.1, 2.0, 1.3 Hz, 1H), 7.50 (t, J=2.2 Hz, 1H), 7.44-7.36 (m, 3H), 7.19 (d, J=8.3 Hz, 1H), 3.91 (s, 3H), 1.35 (s, 18H).

### Synthesis of Compound 40d

40c (13 g, 23.49 mmol, 1.0 eq), bis(pinacolato)diboron (11.9 g, 46.98 mmol, 2.0 eq), Pd(OAc)₂ (52.76 mg, 0.235 mmol, 0.01 eq), KOAc (6.8 g, 69.47 mmol, 3.0 eq), X-phos (1.12 g, 0.235 mmol, 0.1 eq), and toluene (250 ml) were added to a 1000 ml of single-necked flask and subjected to a reaction at 80° C. for 16 hours under the protection of nitrogen. After the reaction was finished, the reaction liquid was filtered and subjected to a rotary evaporation. The obtained residue was sonicated with hexane (200 mL) for 1 hour, left to stand overnight to precipitate a product, and filtered. The filter cake was grounded, pulped with hexane (200 mL) at 80° C. for 2 hours, filtered, and oven-dried to obtain 10.5 g of white solid with a yield of 74.4%.

¹H NMR (400 MHz, CDCl₃) δ 8.13 (d, J=1.9 Hz, 1H), 8.08 (d, J=2.2 Hz, 1H), 8.05 (t, J=1.9 Hz, 1H), 7.96 (d, J=2.2 Hz, 1H), 7.78 (ddd, J=7.7, 1.9, 1.2 Hz, 1H), 7.74 (ddd, J=7.1, 1.9, 1.2 Hz, 1H), 7.71 (dd, J=8.3, 1.9 Hz, 1H), 7.54-7.48 (m, 2H), 7.42 (d, J=2.1 Hz, 2H), 7.19 (d, J=8.3 Hz, 1H), 3.91 (s, 3H), 1.35 (s, 18H), 1.24 (s, 12H).

### Synthesis of Compound 40e

a5 (10 g, 28.18 mmol, 1.0 eq), 40d (33.84 g, 56.36 mmol, 2.0 eq), Pd₂(dba)₃ (322 mg, 0.56 mmol, 0.02 eq), K₃PO₄-3H₂O (22.6 g, 84.85 mmol, 3.0 eq), X-phos (1.3 g, 2.81 mmol, 0.1 eq), and toluene/ethanol/water (120 mL/30 mL/30 mL) were added to a 500 ml of single-necked flask and subjected to a reaction at 90° C. for 7 hours under the protection of nitrogen. After the reaction was finished, the reaction liquid was added with water (200 mL), extract with DCM (400 ml), subjected to a rotary evaporation, and subjected to a separation by silica gel column chromatography (with Hex:EA=5:1 (V/V) as an eluent) to obtain 15.4 g of white solid with a yield of 69.1%.

¹H NMR (400 MHz, CDCl₃) δ 8.75 (d, J=4.6 Hz, 1H), 8.27 (d, J=1.9 Hz, 1H), 8.21 (t, J=2.0 Hz, 1H), 8.17-8.12 (m, 2H), 8.12-8.07 (m, 2H), 7.96 (d, J=2.2 Hz, 1H), 7.89 (dd, J=8.5, 1.7 Hz, 2H), 7.71 (dd, J=8.3, 1.9 Hz, 1H), 7.69-7.64 (m, 1H), 7.64-7.60 (m, 2H), 7.59-7.48 (m, 4H), 7.45-7.36 (m, 6H), 7.36-7.28 (m, 2H), 7.19 (d, J=8.3 Hz, 1H), 3.91 (s, 3H), 1.35 (s, 18H).

### Synthesis of Compound 40f

40e (12 g, 15.13 mmol, 1.0 eq), pyridine hydrochloride (96 g), and o-dichlorobenzene (12 ml) were added to a 500 ml of single-necked flask and subjected to a reaction at 200° C. for 6 hours under the protection of nitrogen. After the reaction was finished, the reaction liquid was added with water and extracted with DCM (200 ml×2). The organic phase was subjected to a rotary evaporation and a separation by silica gel column chromatography (with Hex:EA=5:1 (V/V) as an eluent) to obtain 9.34 g of yellow solid with a yield of 79.3%.

¹H NMR (400 MHz, CDCl₃) δ 8.75 (d, J=4.6 Hz, 1H), 8.27 (d, J=1.9 Hz, 1H), 8.21 (t, J=2.0 Hz, 1H), 8.16-8.12 (m, 1H), 8.12-8.05 (m, 3H), 7.93 (d, J=2.2 Hz, 1H), 7.89 (dd, J=8.5, 1.8 Hz, 2H), 7.71-7.58 (m, 4H), 7.54 (t, J=7.0 Hz, 1H), 7.52-7.47 (m, 3H), 7.45-7.36 (m, 6H), 7.36-7.28 (m, 2H), 7.04 (d, J=8.6 Hz, 1H), 1.35 (s, 18H).

### Synthesis of Complex 40

40f (9 g, 9.25 mmol, 1.0 eq), KPtCl₄ (4.18 g, 11.1 mmol, 1.2 eq), TBAB (151.3 mg, 0.46 mmol, 0.05eq), and acetic acid (900 mL) were added to a 500 ml of single-necked flask and subjected to a reaction at 130° C. for 16 hours under the protection of argon.

After the reaction was finished, the reaction liquid was combined with excess deionized water to precipitate a solid and subjected to suction filtration. The solid was dissolved in dichloromethane, and subjected to a rotary evaporation, a separation by silica gel column chromatography with dichloromethane as an eluent, a further separation by silica gel column chromatography with Hex:DCM:EA=2:1:0.2 as an eluent, and then a recrystallization with DCM:Hex=10 ml:70 ml to obtain 7 g of red solid, which was recrystallized again with DCM:MeOH=51 ml:15 ml to obtain 7.1 g of red solid with a yield of 79.8%. ¹H NMR (400 MHz, CDCl₃) δ 9.07 (d, J=8.9 Hz, 1H), 8.30 (d, J=1.9 Hz, 1H), 8.26 (d, J=1.8 Hz, 1H), 8.18-8.11 (m, 2H), 8.09 (t, J=3.8 Hz, 1H), 7.80-7.69 (m, 2H), 7.69-7.64 (m, 1H), 7.60-7.56 (m, 1H), 7.56-7.53 (m, 3H), 7.52-7.44 (m, 5H), 7.44-7.27 (m, 8H), 7.07 (s, 1H), 1.35 (s, 18H).

¹³C NMR (101 MHz, CDCl₃) δ 167.39, 152.12, 151.60, 148.09, 144.54, 144.37, 140.79, 139.59, 139.45, 139.19, 138.93, 138.92, 137.16, 137.14, 134.47, 132.07, 130.91, 130.05, 128.38, 128.33, 128.06, 127.49, 126.91, 125.96, 125.15, 124.75, 124.17, 123.93, 123.50, 123.47, 123.44, 122.86, 122.84, 122.63, 122.31, 121.69, 121.59, 120.47, 118.10, 115.07, 112.54, 103.68, 34.96, 31.29.

ESI-MS (m/z): 972.3 (M+1)

### Example 4

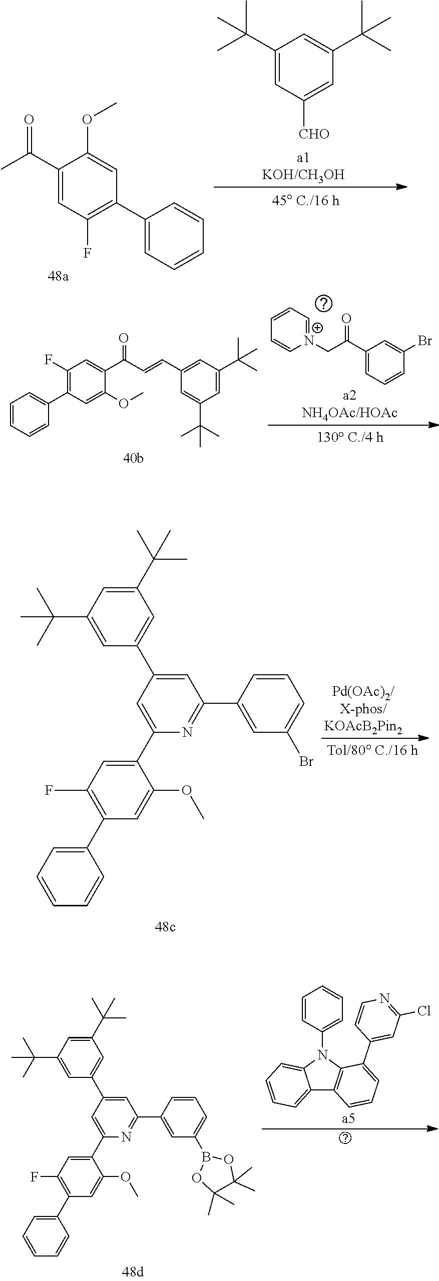

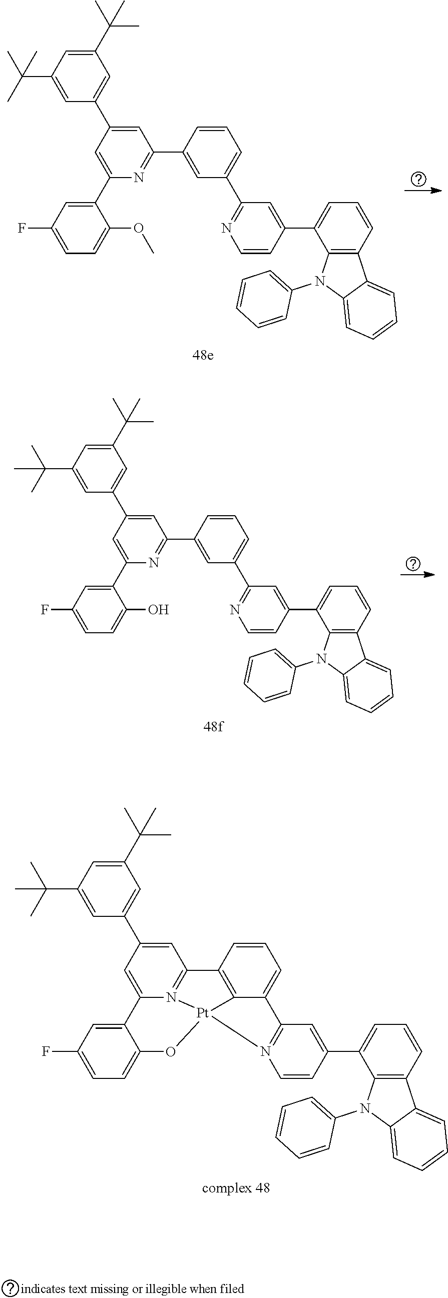

### Synthesis of Compound 48b

48a (10 g, 40.9 mmol, 1.0 eq) was dissolved in methanol (200 ml) in a 1000 ml of single-necked flask. KOH (11.4 g, 204.5 mmol, 5.0 eq) was dissolved in water (100 ml) and the resulting aqueous solution was slowly dropwise added to the flask to obtain a reaction liquid, which was then added with a1 (9.82 g, 44.99 mmol, 1.1 eq) and subjected to a reaction at 45° C. for 16 hours under stirring. After the reaction was finished, the reaction liquid was filtered. The filter cake was pulped with methanol (50 ml×2) and oven-dried to obtain 10.8 g of white solid with a yield of 59.4%.

¹H NMR (400 MHz, CDCl₃) δ 7.77 (d, J=7.9 Hz, 1H), 7.72 (d, J=15.5 Hz, 1H), 7.57 (d, J=15.6 Hz, 1H), 7.50-7.43 (m, 3H), 7.42-7.36 (m, 6H), 3.90 (s, 3H), 1.36 (s, 18H).

### Synthesis of Compound 48c

48b (10 g, 22.5 mmol, 1.0 eq), a2 (10.91 g, 27.0 mmol, 1.2 eq), NH₄OAc (52.0 g, 675 mmol, 30.0 eq), and acetic acid (200 ml) were added to a 500 ml of single-necked flask and subjected to a reaction at 130° C. for 4 hours under the protection of nitrogen. After the reaction was finished, the reaction liquid was filtered to obtain a filter cake, added with water (200 ml), and then extracted with DCM (100 ml×2). The organic phase was subjected to a rotary evaporation to obtain a residue. The residue and the filter cake were pulped with Hex:EA=20:1 (V/V a total of 200 ml) and filtered to obtain a filter cake which was oven-dried to obtain 10.25 g of gray white solid with a yield of 73.2%.

¹H NMR (400 MHz, CDCl₃) δ 8.22 (t, J=1.9 Hz, 1H), 8.10 (d, J=2.2 Hz, 1H), 8.00 (ddd, J=8.6, 1.9, 1.2 Hz, 1H), 7.95 (d, J=2.2 Hz, 1H), 7.66 (d, J=8.0 Hz, 1H), 7.55 (ddd, J=8.1, 2.0, 1.3 Hz, 1H), 7.50 (t, J2=2.2 Hz, 1H), 7.48-7.44 (m, 2H), 7.44-7.36 (m, 6H), 7.32 (d, J=5.1 Hz, 1H), 3.89 (s, 3H), 1.35 (s, 18H).

### Synthesis of Compound 48d

48c (10 g, 16.1 mmol, 1.0 eq), bis(pinacolato)diboron (8.16 g, 32.2 mmol, 2.0 eq), Pd(OAc)₂ (36.1 mg, 0.161 mmol, 0.01 eq), KOAc (4.74 g, 48.3 mmol, 3.0 eq), X-phos (0.77 g, 1.61 mmol, 0.1 eq), and toluene (250 ml) were added to a 1000 ml of single-necked flask and subjected to a reaction at 80° C. for 16 hours under the protection of nitrogen. After the reaction was finished, the reaction liquid was filtered and subjected to a rotary evaporation. The obtained residue was sonicated with hexane (200 mL) for 1 hour, left to stand overnight to precipitate a product, and filtered. The filter cake was grounded, pulped with hexane (200 mL) at 80° C. for 2 hours, filtered, and oven-dried to obtain 7.68 g of white solid with a yield of 71.3%.

¹H NMR (400 MHz, CDCl₃) δ 8.08 (d, J=2.2 Hz, 1H), 8.05 (t, J=1.9 Hz, 1H), 7.95 (d, J=2.2 Hz, 1H), 7.78 (ddd, J=7.7, 1.8, 1.1 Hz, 1H), 7.74 (ddd, J=7.1, 1.9, 1.2 Hz, 1H), 7.66 (d, J=8.0 Hz, 1H), 7.54-7.49 (m, 2H), 7.48-7.44 (m, 2H), 7.44-7.35 (m, 5H), 7.32 (d, J=5.1 Hz, 1H), 3.89 (s, 3H), 1.35 (s, 18H), 1.24 (s, 12H).

### Synthesis of Compound 48e

a5 (2.47 g, 6.97 mmol, 1.0 eq), 48d (7 g, 10.45 mmol, 1.5 eq), Pd₂(dba)₃ (78.05 mg, 0.14 mmol, 0.02 eq), K₃PO₄-3H₂O (5.57 g, 20.91 mmol, 3.0 eq), X-phos (1.3 g, 2.81 mmol, 0.1 eq), and toluene/ethanol/water (120 mL/30 mL/30 mL) were added to a 500 ml of single-necked flask and subjected to a reaction at 90° C. for 7 hours under the protection of nitrogen. After the reaction was finished, the reaction liquid was added with water (200 mL), extracted with DCM (400 ml), subjected to a rotary evaporation, and subjected to a separation by silica gel column chromatography (with Hex:EA=5:1 (V/V) as an eluent) to obtain 3.9 g of white solid with a yield of 65.6%.

¹H NMR (400 MHz, CDCl₃) δ 8.75 (d, J=4.6 Hz, 1H), 8.27 (d, J=1.9 Hz, 1H), 8.21 (t, J=1.9 Hz, 1H), 8.19-8.12 (m, 1H), 8.12-8.07 (m, 2H), 7.95 (d, J=2.2 Hz, 1H), 7.89 (dd, J=8.5, 1.7 Hz, 2H), 7.70-7.60 (m, 4H), 7.54 (t, J=7.0 Hz, 1H), 7.52-7.35 (m, 14H), 7.35-7.28 (m, 3H), 3.89 (s, 3H), 1.35 (s, 18H).

### Synthesis of Compound 48f

48e (3.5 g, 4.1 mmol, 1.0 eq), pyridine hydrochloride (35 g), and o-dichlorobenzene (3.5 ml) were added to a 500 ml of single-necked flask and subjected to a reaction at 200° C. for 6 hours under the protection of nitrogen. After the reaction was finished, the reaction liquid was added with water and extracted with DCM (200 ml×2). The organic phase was subjected to a rotary evaporation and a separation by silica gel column chromatography (with Hex:EA=5:1 (V/V) as an eluent) to obtain 2.97 g of yellow solid with a yield of 86.3%.

¹H NMR (400 MHz, CDCl₃) δ 8.75 (d, J=4.6 Hz, 1H), 8.27 (d, J=1.9 Hz, 1H), 8.21 (t, J=1.9 Hz, 1H), 8.16-8.12 (m, 1H), 8.12-8.07 (m, 2H), 7.92-7.85 (m, 3H), 7.70-7.60 (m, 3H), 7.57-7.52 (m, 2H), 7.52-7.44 (m, 5H), 7.44-7.36 (m, 9H), 7.34-7.28 (m, 2H), 7.22 (d, J=4.9 Hz, 1H), 1.35 (s, 18H).

### Synthesis of Complex 48

48f (2.5 g, 2.95 mmol, 1.0 eq), KPtCl₄ (1.33 g, 3.54 mmol, 1.2 eq), TBAB (48.3 mg, 0.15 mmol, 0.05 eq), and acetic acid (250 mL) were added to a 500 ml of single-necked flask and subjected to a reaction at 130° C. for 16 hours under the protection of argon.

After the reaction was finished, the reaction liquid was combined with excess deionized water to precipitate a solid and subjected to a suction filtration. The solid was dissolved in dichloromethane, and subjected to a rotary evaporation, a separation by silica gel column chromatography with DCM as an eluent, a further separation by silica gel column chromatography with Hex:DCM:EA=2:1:0.2 as an eluent, and a recrystallization with DCM:Hex=10 ml:70 ml to obtain 7 g of red solid, which was recrystallized again with DCM:MeOH=51 ml: 15 ml to obtain 2.31 g of red solid with a yield of 75.1%.

¹H NMR (400 MHz, CDCl₃) δ 9.08 (d, J=8.9 Hz, 1H), 8.26 (d, J=1.8 Hz, 1H), 8.17-8.02 (m, 3H), 7.78-7.69 (m, 2H), 7.69-7.65 (m, 1H), 7.62-7.56 (m, 1H), 7.56-7.52 (m, 3H), 7.52-7.35 (m, 14H), 7.35-7.28 (m, 2H), 7.25 (s, 1H), 7.07 (s, 1H), 1.35 (s, 18H).

¹³C NMR (101 MHz, CDCl₃) δ 152.13, 151.60, 148.09, 144.57, 144.37, 140.83, 139.59, 139.19, 138.93, 138.92, 137.16, 137.14, 134.47, 130.05, 129.06, 128.52, 128.38, 128.33, 128.06, 127.98, 127.96, 127.49, 126.91, 125.49, 125.15, 124.75, 124.17, 123.93, 123.50, 123.47, 123.44, 122.86, 122.84, 122.63, 122.16, 121.69, 121.59, 120.47, 112.88, 112.72, 112.54, 111.49, 111.42, 34.96, 31.29.

ESI-MS (m/z): 1041.3 (M+1)

### Example 5

Under nitrogen atmosphere, fully dried samples of platinum complexes 22, 38, 40, and 48 were each weighted at approximately 5.0 mg and subjected to a heating scan at a rate of 10° C./min within a range of 25-800° C. The determined thermal decomposition temperatures (corresponding to a thermal weight loss of 0.5%) were 452° C., 476° C., 457.3° C., and 483° C., respectively, suggesting the excellent thermal stability of these complexes.

### Example 6

An organic light-emitting diode was prepared using the complex luminescent material of the present application, and the structure of the device is as shown in the FIGURE.

Firstly, a transparent conductive ITO glass substrate 10 (provided with an anode 20 thereon) was washed sequentially with a detergent solution and deionized water, ethanol, acetone, and deionized water, and then treated with oxygen plasma for 30 seconds.

Then, HATCN was evaporated onto ITO as a hole injection layer 30 with a thickness of 10 nm.

Then, the compound HT was evaporated to form a hole transport layer 40 with a thickness of 40 nm.

Then, a light-emitting layer 50 with a thickness of 20 nm was evaporated onto the hole transport layer. The light-emitting layer was formed of the platinum complex 22 (20%) in combination with CBP (80%).

Then, AlQ₃ was evaporated onto the light-emitting layer as an electron transport layer 60 with a thickness of 40 nm.

Finally, 1 nm LiF was evaporated as an electron injection layer 70 and 100 nm A1 was evaporated as a cathode 80 of the device.

Example 7: An organic light-emitting diode was prepared by the method as described in Example 6, with the complex 22 replaced by the complex 38.

Example 8: An organic light-emitting diode was prepared by the method as described in Example 6, with the complex 22 replaced by the complex 40.

Example 9: An organic light-emitting diode was prepared by the method as described in Example 6, with the complex 22 replaced by the complex 48.

### Comparative Example 1

An organic light-emitting diode was prepared by the method as described in Example 6, with the complex 22 replaced by a complex Ref-1 (CN110872325A).

### Comparative Example 2

An organic light-emitting diode was prepared by the method as described in Example 6, with the complex 22 replaced by a complex Ref-2 (Chem. Sci., 2014, 5, 4819).

### Comparative Example 3

An organic light-emitting diode was prepared by the method as described in Example 6, with the complex 22 replaced by a complex Ref-3 (CN110872325A).

### Comparative Example 4

An organic light-emitting diode was prepared by the method as described in Example 6, with the complex 22 replaced by a complex Ref-4 (CN110872325A).

The structural formulas of HATCN, HT, AlQ₃, Ref-1, Ref-2, Ref-3, Ref-4, and CBP in the device are as follows:

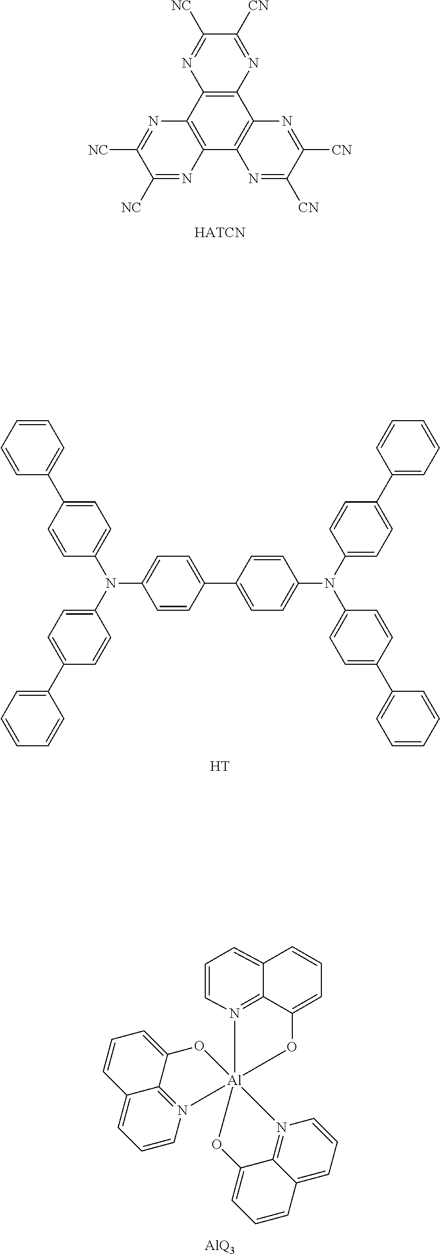

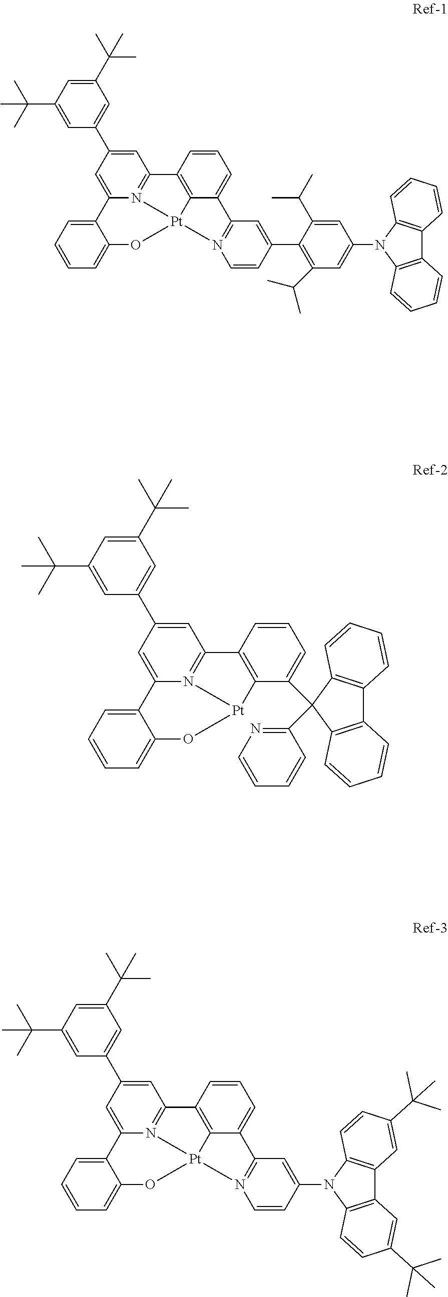

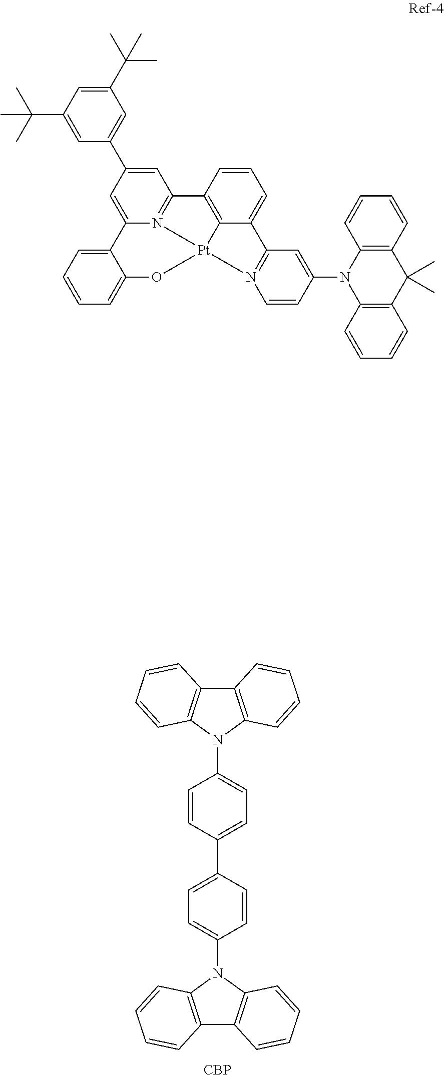

The device properties of the organic electroluminescent devices in Examples 6-9 and Comparative examples 1-4 at a current density of 20 mA/cm² are listed in Table 1:

TABLE 1

| | | Driving | Luminous | Half-peak |
|---|---|---|---|---|
| Device No. | Complex | voltage | efficiency | width |
| Example 6 | Complex 22 | 1 | 1 | 1 |
| Example 7 | Complex 38 | 0.95 | 1.1 | 0.82 |
| Example 8 | Complex 40 | 0.89 | 1.2 | 0.71 |
| Example 9 | Complex 48 | 1.03 | 1.2 | 0.77 |
| Comparative | Ref-1 | 1.12 | 0.95 | 1.2 |
| example 1 | | | | |
| Comparative | Ref-2 | 1.12 | 0.91 | 1.3 |
| example 2 | | | | |
| Comparative | Ref-3 | 1.09 | 0.72 | 1.5 |
| example 3 | | | | |
| Comparative | Ref-4 | 1.07 | 0.83 | 1.5 |
| example 4 | | | | |

Note:
The properties of the device were tested with Example 6 as a benchmark, with individual indicators of properties of the device in Example 6 as 1. The narrower the half-peak width, the higher the color purity, and the better quantum efficiency can be achieved.

From the data shown in Table 1, it can be seen that under the same condition, the platinum complex materials of the present application can be used to prepare the organic light-emitting diodes with lower driving voltages and higher luminous efficiencies. In addition, the device lifespans of the organic light-emitting diodes based on the complexes of the present application are significantly longer as compared to the complex materials in the Comparative Examples, meeting the requirements on the luminescent materials in the display industry and having good industrialization prospects.

The various embodiments as described above are only used as examples, and are not intended to limit the scope of the present application. Other materials and structures may be used to replace the various materials and structures in the present application without departing from the spirit of the present application. It should be understood that various modifications and changes may be made by those skilled in the art according to the concept of the present application without creative effort. Therefore, all technical solutions obtained by those skilled in the art through analysis, inference, or partial research on basis of the existing technologies shall fall within the scope of protection defined by the claims.

1. A divalent platinum complex, being a compound having a structure of formula (I): 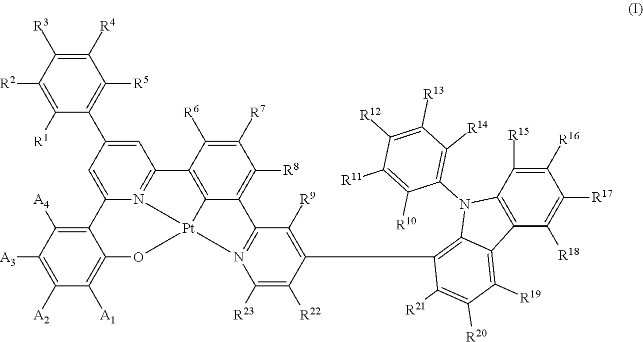
wherein,
R¹ to R²³ are each independently selected from hydrogen, deuterium, halogen, amino, carbonyl, carboxyl, thioalkyl, cyano, sulfonyl, phosphino, a substituted or unsubstituted alkyl having 1 to 20 carbon atoms, a substituted or unsubstituted cycloalkyl having 3 to 20 ring carbon atoms, a substituted or unsubstituted alkenyl having 2 to 20 carbon atoms, a substituted or unsubstituted alkoxy having 1 to 20 carbon atoms, a substituted or unsubstituted aryl having 6 to 30 carbon atoms, or a substituted or unsubstituted heteroaryl having 3 to 30 carbon atoms, or any two adjacent substituents are linked or fused to form a ring;
A₁ to A₄ are each independently selected from hydrogen, deuterium, halogen, amino, carbonyl, carboxyl, thioalkyl, cyano, sulfonyl, phosphino, a substituted or unsubstituted alkyl having 1 to 20 carbon atoms, a substituted or unsubstituted cycloalkyl having 3 to 20 ring carbon atoms, a substituted or unsubstituted alkenyl having 2 to 20 carbon atoms, a substituted or unsubstituted alkoxy having 1 to 20 carbon atoms, an aryl having 6 to 30 carbon atoms, or a substituted or unsubstituted heteroaryl having 3 to 30 carbon atoms, or any two adjacent substituents are linked or fused to form a ring;
the heteroaryl containing a heteroatom including one or more of N, S, or O; and the “substituted” refers to substitution with halogen, deuterium, amino, cyano, or C1-C4 alkyl.

2. The divalent platinum complex of claim 1, wherein R¹ to R²³ are each independently selected from hydrogen, deuterium, halogen, amino, thioalkyl, cyano, a substituted or unsubstituted alkyl having 1 to 6 carbon atoms, a substituted or unsubstituted cycloalkyl having 3 to 6 ring carbon atoms, a substituted or unsubstituted alkenyl having 2 to 6 carbon atoms, a substituted or unsubstituted alkoxy having 1 to 6 carbon atoms, a substituted or unsubstituted aryl having 6 to 12 carbon atoms, or a substituted or unsubstituted heteroaryl having 3 to 6 carbon atoms;
one or more of A₁ to A₄ are selected from hydrogen, deuterium, halo, cyano group, a substituted or unsubstituted alkyl having 1 to 20 carbon atoms, a substituted or unsubstituted cycloalkyl having 3 to 20 ring carbon atoms, a substituted or unsubstituted alkenyl having 2 to 20 carbon atoms, an aryl having 6 to 30 carbon atoms, or a substituted or unsubstituted heteroaryl having 3 to 30 carbon atoms.

3. The divalent platinum complex of claim 2, wherein R¹ to R²³ are each independently selected from hydrogen, deuterium, halogen, or a substituted or unsubstituted alkyl having 1 to 6 carbon atoms;
one or more of A₁ to A₄ are selected from halogen, cyano, a substituted or unsubstituted alkyl having 1 to 6 carbon atoms, a substituted or unsubstituted cycloalkyl having 3 to 12 ring carbon atoms, a substituted or unsubstituted alkenyl having 2 to 12 carbon atoms, an aryl having 6 to 30 carbon atoms, or a substituted or unsubstituted heteroaryl having 3 to 30 carbon atoms, and the rest are hydrogen.

4. The divalent platinum complex of claim 3, wherein R¹ to R²³ are each independently selected from hydrogen, deuterium, methyl, or tert-butyl;
one or more of A₁ to A₄ are selected from fluorine, cyano, methyl, tert-butyl, phenyl, cyanophenyl, or pyridyl and the rest are hydrogen.

5. A divalent platinum complex of claim 1, wherein R⁶ to R²³ in R¹ to R²³ are hydrogen.

6. The divalent platinum complex of claim 5, wherein at least one of R¹ to R⁵ is not hydrogen.

7. The divalent platinum complex of claim 6, wherein R² and R⁴ in R¹ to R⁵ are not hydrogen, and R¹ and R⁵ in R¹ to R⁵ are hydrogen.

8. The divalent platinum metal complex of claim 1, being one of the following compounds:

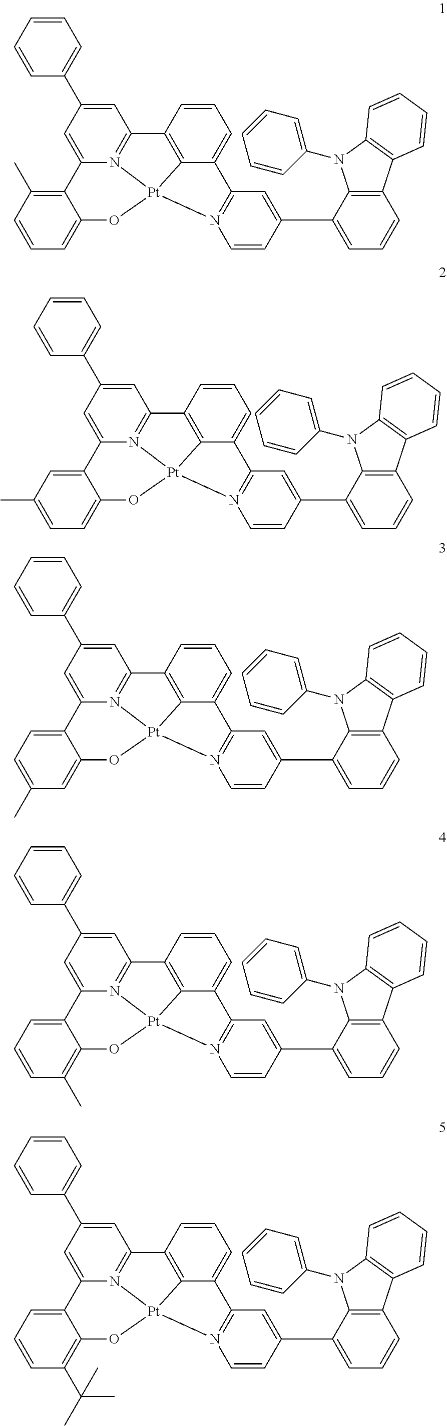

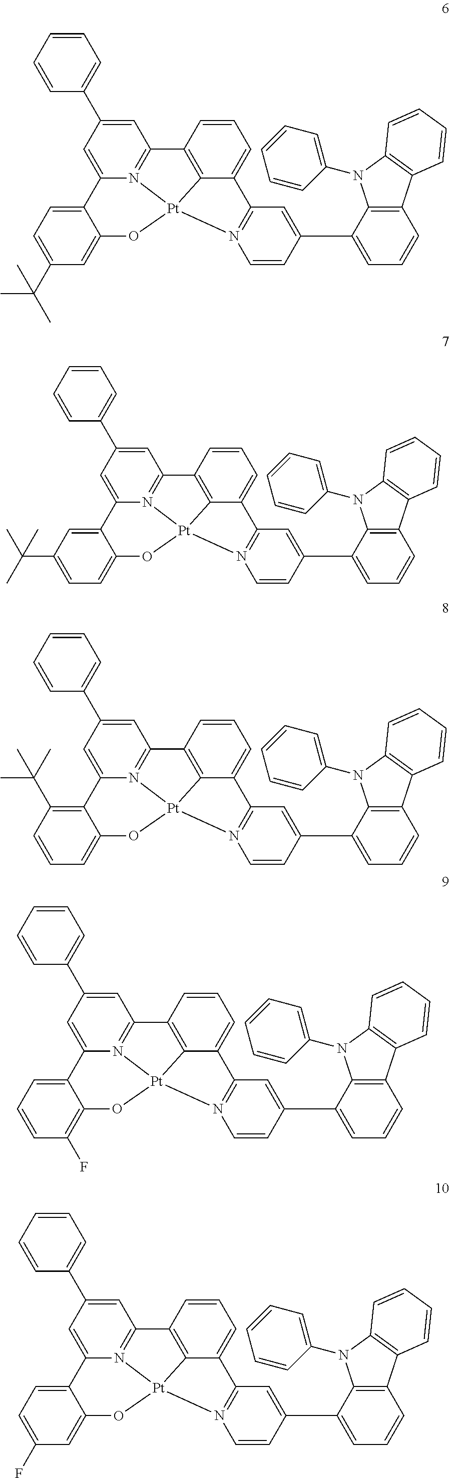

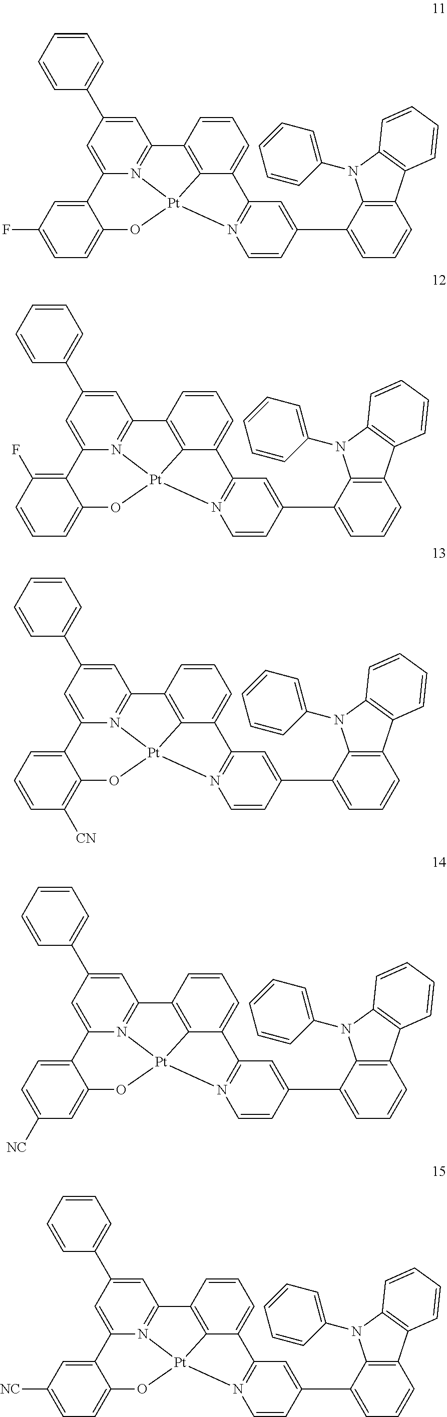

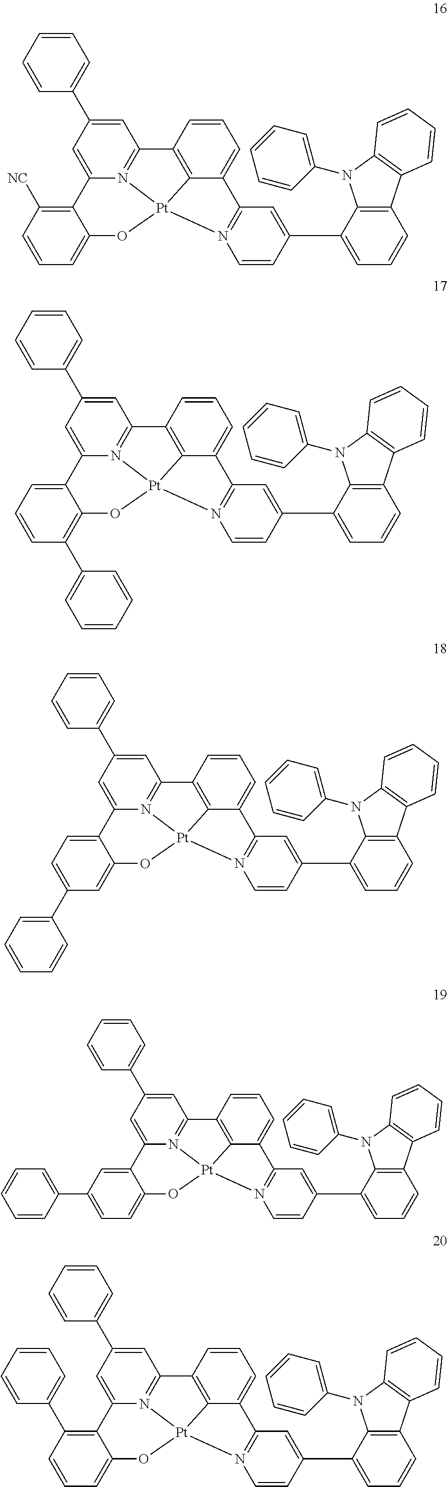

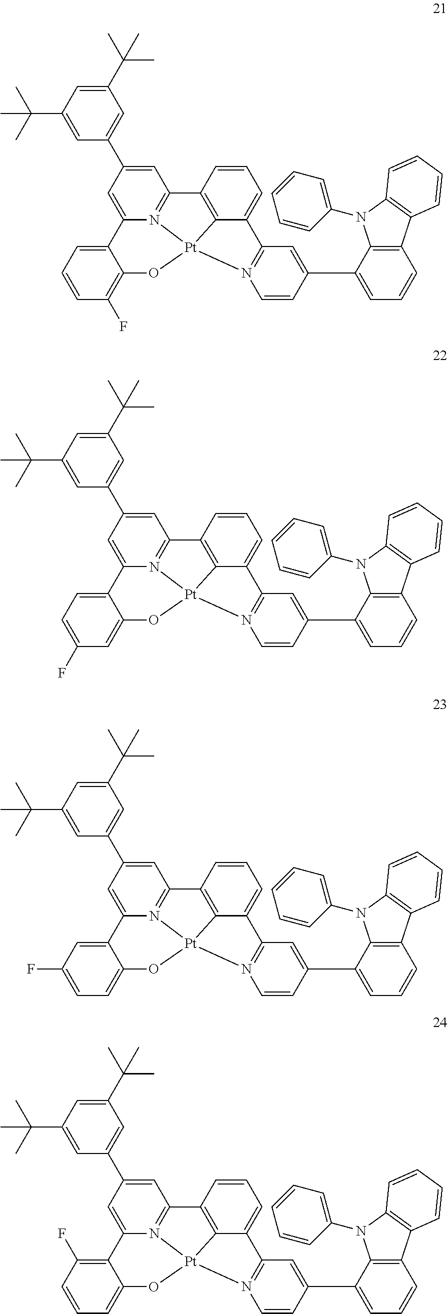

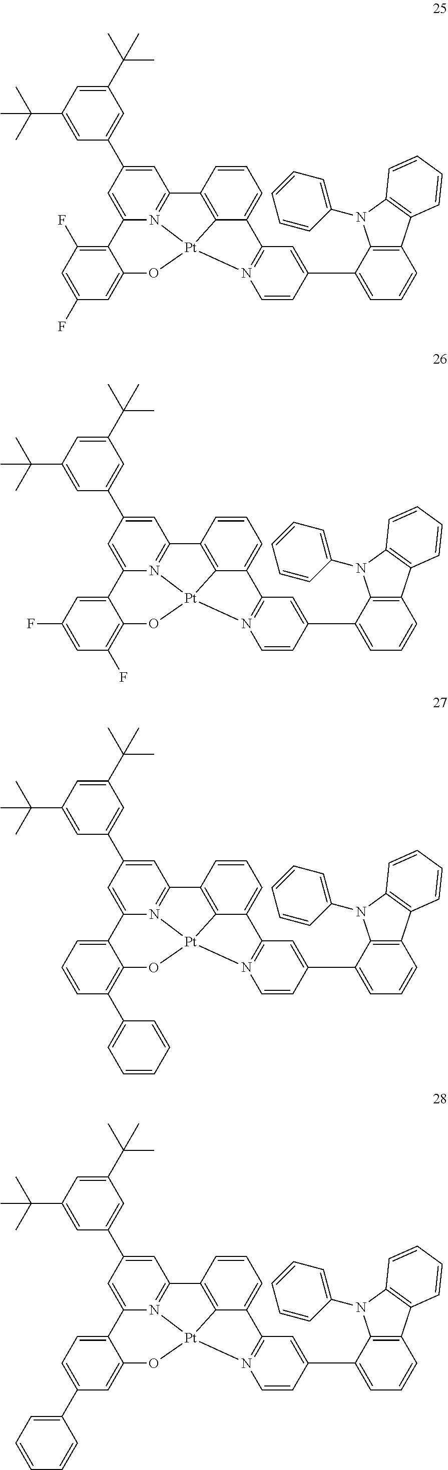

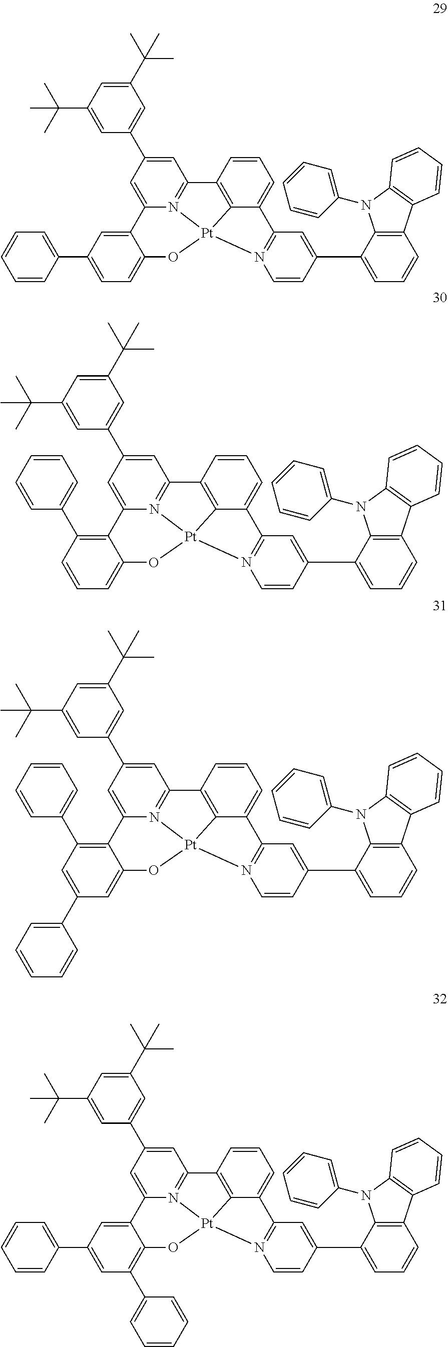

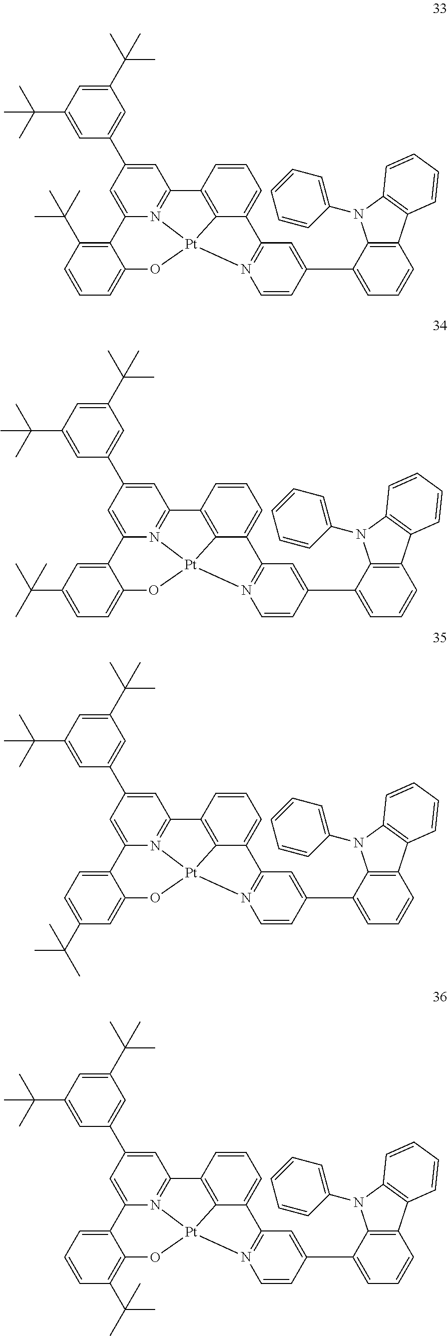

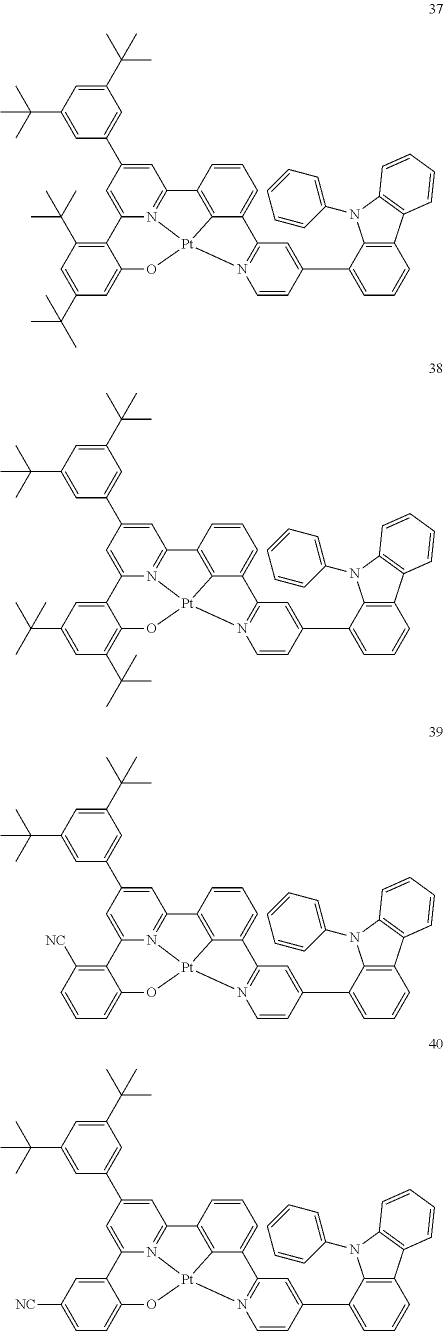

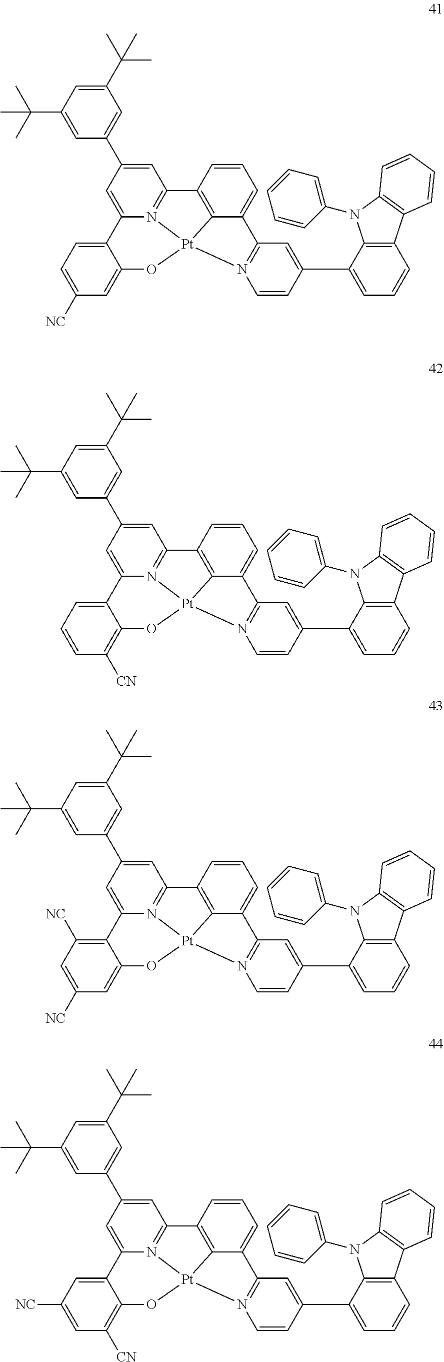

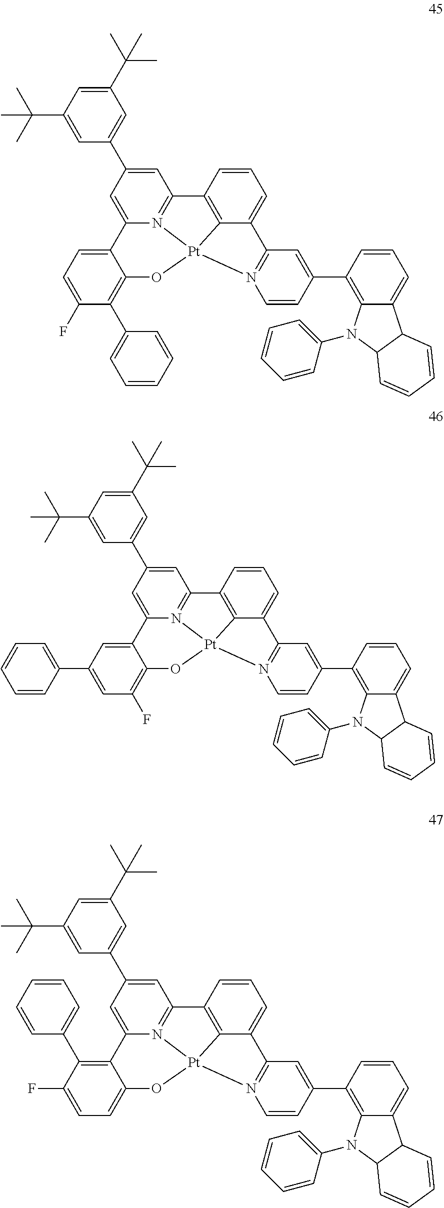

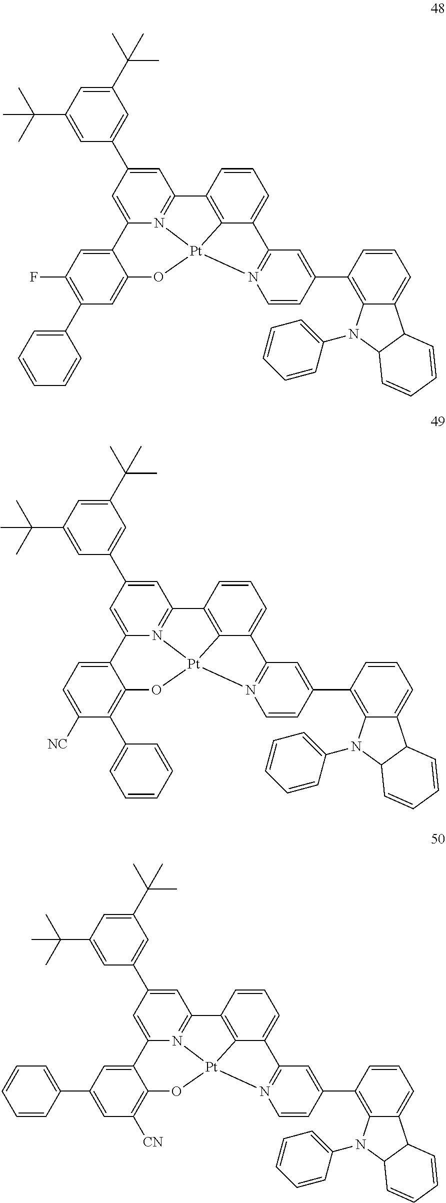

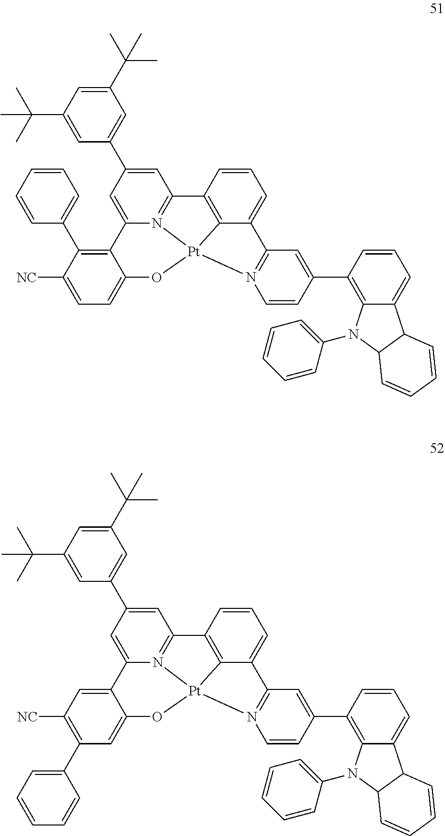

9. A precursor of the divalent platinum complex of claim 1, having the following structural formula:

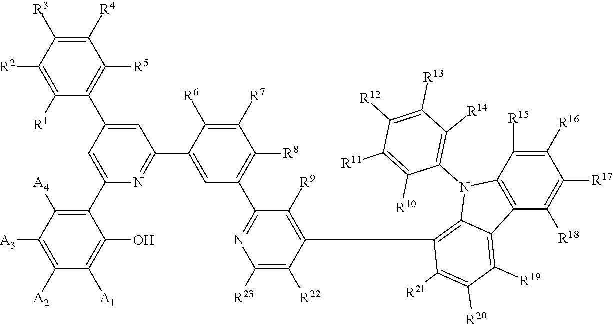

10. A device comprising the divalent platinum complex of claim 1, wherein the device is an organic light-emitting diode, an organic thin film transistor, an organic photovoltaic device, a luminescent electrochemical cell, or a chemical sensor.

11. An organic light-emitting diode, comprising a cathode, an anode, and an organic layer, wherein the organic layer comprises one or more of a hole injection layer, a hole transport layer, a light-emitting layer, a hole blocking layer, an electron injection layer, or an electron transport layer, and the organic layer comprises the divalent platinum complex of claim 1.

12. The organic light-emitting diode of claim 11, wherein the light-emitting layer comprises the divalent platinum complex of claim 1.

13. An organic light-emitting diode, comprising a cathode, an anode, and an organic layer, wherein the organic layer comprises one or more of a hole injection layer, a hole transport layer, a light-emitting layer, a hole blocking layer, an electron injection layer, or an electron transport layer, and the organic layer comprises the divalent platinum complex of claim 2.

14. An organic light-emitting diode, comprising a cathode, an anode, and an organic layer, wherein the organic layer comprises one or more of a hole injection layer, a hole transport layer, a light-emitting layer, a hole blocking layer, an electron injection layer, or an electron transport layer, and the organic layer comprises the divalent platinum complex of claim 3.

15. An organic light-emitting diode, comprising a cathode, an anode, and an organic layer, wherein the organic layer comprises one or more of a hole injection layer, a hole transport layer, a light-emitting layer, a hole blocking layer, an electron injection layer, or an electron transport layer, and the organic layer comprises the divalent platinum complex of claim 4.

16. An organic light-emitting diode, comprising a cathode, an anode, and an organic layer, wherein the organic layer comprises one or more of a hole injection layer, a hole transport layer, a light-emitting layer, a hole blocking layer, an electron injection layer, or an electron transport layer, and the organic layer comprises the divalent platinum complex of claim 5.

17. An organic light-emitting diode, comprising a cathode, an anode, and an organic layer, wherein the organic layer comprises one or more of a hole injection layer, a hole transport layer, a light-emitting layer, a hole blocking layer, an electron injection layer, or an electron transport layer, and the organic layer comprises the divalent platinum complex of claim 6.

18. An organic light-emitting diode, comprising a cathode, an anode, and an organic layer, wherein the organic layer comprises one or more of a hole injection layer, a hole transport layer, a light-emitting layer, a hole blocking layer, an electron injection layer, or an electron transport layer, and the organic layer comprises the divalent platinum complex of claim 7.

19. An organic light-emitting diode, comprising a cathode, an anode, and an organic layer, wherein the organic layer comprises one or more of a hole injection layer, a hole transport layer, a light-emitting layer, a hole blocking layer, an electron injection layer, or an electron transport layer, and the organic layer comprises the divalent platinum complex of claim 8.
